(19) United States
(12) Patent Application Publication
(10) Pub. No.: US 2024/0413081 A1
(43) Pub. Date: Dec. 12, 2024

(54) SEMICONDUCTOR DEVICE

(71) Applicant: Samsung Electronics Co., Ltd., Suwon-si (KR)

(72) Inventors: Sun Jung Lee, Suwon-si (KR); Sang Hoon Ahn, Suwon-si (KR); Dong Gon Yoo, Suwon-si (KR); Jeong Won Hwang, Suwon-si (KR)

(21) Appl. No.: 18/652,067

(22) Filed: May 1, 2024

(30) Foreign Application Priority Data
Jun. 8, 2023 (KR) 10-2023-0073486
Nov. 1, 2023 (KR) 10-2023-0149144

(51) Int. Cl. H01L 23/528; H01L 23/522; H01L 23/532

(52) U.S. Cl. CPC H01L 23/5283; H01L 23/5226; H01L 23/53257

(57) ABSTRACT

A semiconductor device includes a via pattern in a first interlayer insulating film, and a wiring pattern that extends in a first direction and is on the first interlayer insulating film and the via pattern. The wiring pattern includes a lower wiring line and an upper wiring line on the lower wiring line, where the lower wiring line and the upper wiring line are stacked in a second direction, where the lower wiring line is between the via pattern and the upper wiring line and is on an upper surface of the via pattern, where a first portion of the lower wiring line is on the upper surface of the via pattern and has a first thickness, and where a second portion of the lower wiring line is on an upper surface of the first interlayer insulating film and has a second thickness.

### CROSS-REFERENCE TO RELATED APPLICATIONS

This application claims priority from Korean Patent Application No. 10-2023-0149144 filed on Nov. 1, 2023 and Korean Patent Application No. 10-2023-0073486 filed on Jun. 8, 2023 in the Korean Intellectual Property Office and all the benefits accruing therefrom under 35 U.S.C. 119, the contents of which in its entirety are herein incorporated by reference.

### TECHNICAL FIELD

The present disclosure relates to a semiconductor device, and more specifically, to a semiconductor device including a wiring line formed in a BEOL (Back-End-Of-Line) process.

### BACKGROUND

In recent years, as down-scaling of semiconductor elements has progressed rapidly due to the development of electronic technology, semiconductor chips are desired to have higher integration and lower power consumption. In order to cope with the requirements for higher integration and lower power consumption of the semiconductor chips, feature sizes of the semiconductor devices continue to decrease.

As various contact forms are used for connection between the wirings, the length of the contacts may increase. A contact resistance may increase accordingly.

### SUMMARY

Aspects of the present disclosure provide a semiconductor device that may improve element performance and reliability, by using a wiring pattern of a stacked structure formed of metal.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

According to an aspect of the present disclosure, there is provided a semiconductor device comprising a via pattern in a first interlayer insulating film, and a wiring pattern that extends in a first direction and is on the first interlayer insulating film and the via pattern, where the wiring pattern includes a lower wiring line and an upper wiring line on the lower wiring line, where the lower wiring line and the upper wiring line are stacked in a second direction, where the lower wiring line is between the via pattern and the upper wiring line and is on an upper surface of the via pattern, where a first portion of the lower wiring line is on the upper surface of the via pattern and has a first thickness, and where a second portion of the lower wiring line is on an upper surface of the first interlayer insulating film and has a second thickness that is different from the first thickness.

According to another aspect of the present disclosure, there is provided a semiconductor device comprising a via pattern in a first interlayer insulating film, a wiring pattern that extends in a first direction and is on the first interlayer insulating film and the via pattern, where the wiring pattern includes a lower wiring line and an upper wiring line on the lower wiring line, and where the lower wiring line and the upper wiring line are stacked in a second direction, and a second interlayer insulating film that is on the first interlayer insulating film, where the second interlayer insulating film includes a wiring insulating liner that extends along a side wall of the wiring pattern and an upper surface of the first interlayer insulating film, and where the second interlayer insulating film includes a filling interlayer insulating film on the wiring insulating liner, where the upper wiring line includes an upper surface and a bottom surface that are opposite to each other in the second direction, where the upper wiring line includes a side wall that contacts the upper surface of the upper wiring line and the bottom surface of the upper wiring line, where the lower wiring line is between an upper surface of the via pattern and the bottom surface of the upper wiring line, where the lower wiring line contacts the upper surface of the via pattern, and where the lower wiring line does not extend along the side wall of the upper wiring line.

According to still another aspect of the present disclosure, there is provided a semiconductor device comprising a via pattern in a first interlayer insulating film, and a wiring pattern that extends in a first direction and is on the first interlayer insulating film and the via pattern, where the wiring pattern includes a lower wiring line and an upper wiring line on the lower wiring line, and where the lower wiring line and the upper wiring line are stacked in a second direction, where the upper wiring line includes an upper surface and a bottom surface opposite to each other in the second direction, where the upper wiring line includes a side wall that connects the upper surface of the upper wiring line and the bottom surface of the upper wiring line, where the lower wiring line is between an upper surface of the via pattern and the bottom surface of the upper wiring line, where the lower wiring line contacts the upper surface of the via pattern, where the lower wiring line includes a first portion that extends along a part of the side wall of the upper wiring line and a second portion that extends along the bottom surface of the upper wiring line, and where the upper wiring line overlaps the uppermost surface of the lower wiring line in the first direction.

### BRIEF DESCRIPTION OF DRAWINGS

FIG. 1 is an example layout diagram for explaining a semiconductor device according to some embodiments.

FIG. 2 is a cross-sectional view taken along line A-A of FIG. 1.

FIG. 3 is a cross-sectional view taken along line B-B of FIG. 1.

FIG. 4 is an enlarged view of a portion P of FIG. 3.

FIGS. 5, 6, and 7 are diagrams for explaining a semiconductor device according to some embodiments.

FIGS. 8 and 9 are diagrams of a semiconductor device according to some embodiments.

FIG. 10 is a diagram of the semiconductor device according to some embodiments.

FIG. 11 is a diagram of a semiconductor device according to some embodiments.

FIGS. 12, 13, and 14 are diagrams of a semiconductor device according to some embodiments.

FIGS. 15 and 16 are diagrams of a semiconductor device according to some embodiments.

FIGS. 17 and 18 are diagrams of a semiconductor device according to some embodiments.

FIGS. 19, 20, 21, and 22 are diagrams of a semiconductor device according to some embodiments.

FIG. 23 is a diagram of a semiconductor device according to some embodiments.

FIGS. 24 and 25 are diagrams of a semiconductor device according to some embodiments.

FIGS. 26 and 27 are diagrams of a semiconductor device according to some embodiments.

FIGS. 28 and 29 are diagrams of a semiconductor device according to some embodiments.

FIG. 30 is a diagram of a semiconductor device according to some embodiments.

FIG. 31 is a diagram of a semiconductor device according to some embodiments.

FIGS. 32, 33, and 34 are diagrams of a semiconductor device according to some embodiments.

FIGS. 35, 36, and 37 are intermediate stage diagrams of a method for fabricating a semiconductor device according to some embodiments.

FIGS. 38, 39, 40, 41, and 42 are intermediate stage diagrams of a method for fabricating a semiconductor device according to some embodiments.

FIGS. 43, 44, 45, 46, and 47 are intermediate stage diagrams of a method for fabricating a semiconductor device according to some embodiments.

FIGS. 48, 49, 50, and 51 are intermediate stage diagrams of a method for fabricating a semiconductor device according to some embodiments.

FIGS. 52 and 53 are intermediate stage diagrams of a method for fabricating a semiconductor device according to some embodiments.

### DETAILED DESCRIPTION OF THE EMBODIMENTS

To clarify the present disclosure, parts that are not connected with the description will be omitted, and the same elements or equivalents are referred to by the same reference numerals throughout the specification. Further, since sizes and thicknesses of constituent members shown in the accompanying drawings are arbitrarily given for better understanding and ease of description, the present disclosure is not limited to the illustrated sizes and thicknesses. In the drawings, the thickness of layers, films, panels, regions, etc., are exaggerated for clarity. In the drawings, for better understanding and ease of description, thicknesses of some layers and areas are excessively displayed.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, spatially relative terms, such as “beneath,” “below,” “lower,” “above,” “upper,” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations), and the spatially relative descriptors used herein may be interpreted accordingly.

In addition, unless explicitly described to the contrary, the word “comprises”, and variations such as “comprises” or “comprising”, will be understood to imply the inclusion of stated elements but not the exclusion of any other elements. As used herein, the phrase “at least one of A, B, and C” refers to a logical (A OR B OR C) using a non-exclusive logical OR, and should not be construed to mean “at least one of A, at least one of B and at least one of C.” As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, steps, operations, elements and/or components, but do not preclude the presence or addition of one or more other features, steps, operations, elements, components and/or groups thereof. The term “and/or” includes any and all combinations of one or more of the associated listed items. The term “connected” may be used herein to refer to a physical and/or electrical connection and may refer to a direct or indirect physical and/or electrical connection. Components or layers described with reference to “overlap” in a particular direction may be at least partially obstructed by one another when viewed along a line extending in the particular direction or in a plane perpendicular to the particular direction.

Although terms such as first and second are used to describe various elements or components in the present specification, it goes without saying that these elements or components are not limited by these terms. These terms are only used to distinguish a single element or component from other elements or components. Therefore, it goes without saying that a first element or component referred to below may be a second element or component within the technical idea of the present disclosure.

Although drawings of a semiconductor device according to some embodiments show a fin-type transistor (FinFET) including a channel region of a fin-type pattern shape, a transistor including a nanowire or a nanosheet, a MBCFET™ (Multi-Bridge Channel Field Effect Transistor) or a vertical transistor (Vertical FET) as an example, the embodiments are not limited thereto. The semiconductor device according to some embodiments may, of course, include a tunneling transistor (tunneling FET) or a three-dimensional (3D) transistor. The semiconductor device according to some embodiments may include a planar transistor. In addition, the technical idea of the present disclosure may be applied to a transistor based on two-dimensional material (2D material based FETs) and a heterostructure thereof.

Further, the semiconductor device according to some embodiments may also include a bipolar junction transistor, a laterally diffused metal oxide semiconductor (LDMOS), or the like.

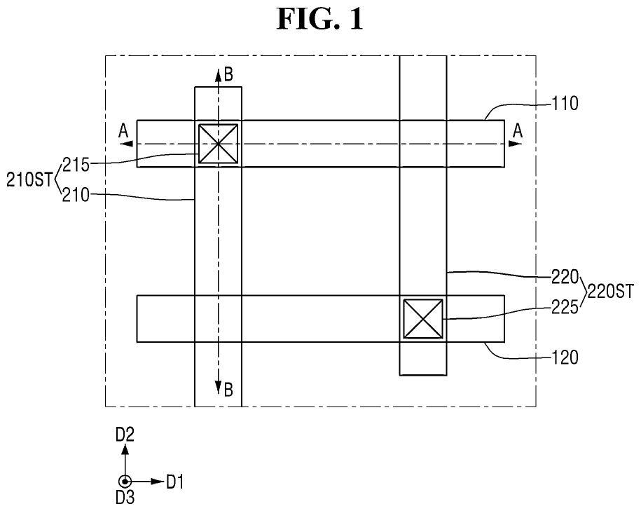

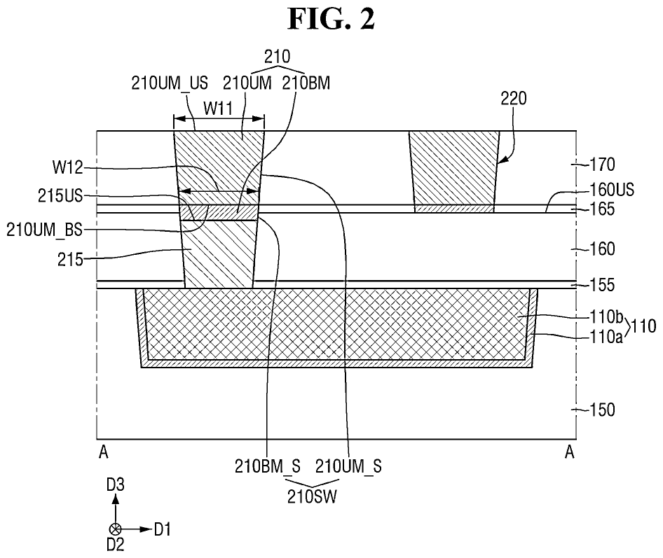

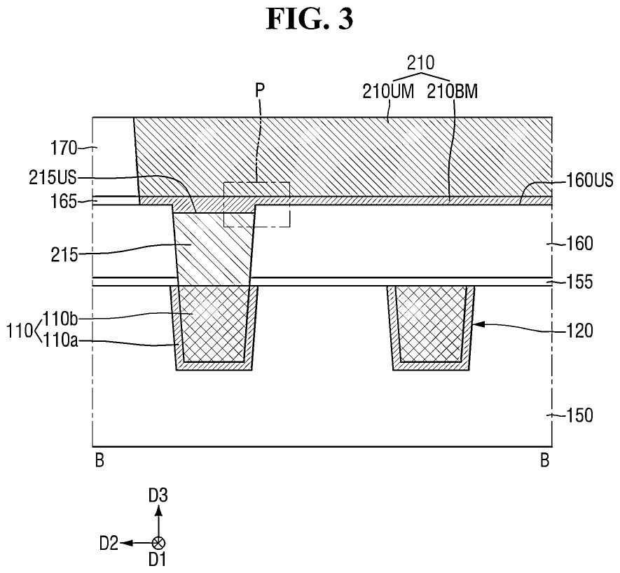

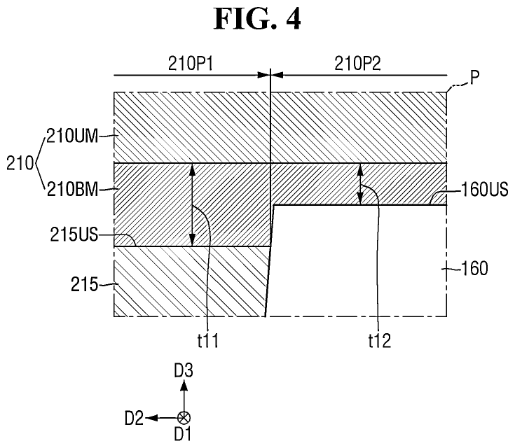

FIG. 1 is an example layout diagram of a semiconductor device according to some embodiments. FIG. 2 is a cross-sectional view taken along line A-A of FIG. 1. FIG. 3 is a cross-sectional view taken along line B-B of FIG. 1. FIG. 4 is an enlarged view of a portion P of FIG. 3.

Referring to FIGS. 1 to 4, a semiconductor device according to some embodiments may include a first conductive lower pattern 110, a second conductive lower pattern 120, a first upper wiring structure 210ST, and a second upper wiring structure 220ST.

The first conductive lower pattern 110 and the second conductive lower pattern 120 may each be disposed inside the first interlayer insulating film 150. The first conductive lower pattern 110 and the second conductive lower pattern 120 may each extend long in a first direction D1. The first conductive lower pattern 110 and the second conductive lower pattern 120 may be spaced apart from each other in a second direction D2.

The first conductive lower pattern 110 and the second conductive lower pattern 120 may each have a linear shape extending in the first direction D1. For example, the first direction D1 may be a longitudinal direction of the first conductive lower pattern 110 and the second conductive lower pattern 120, and the second direction D2 may be a width direction of the first conductive lower pattern 110 and the second conductive lower pattern 120. Here, the first direction D1 intersects the second direction D2 and the third direction D3. The second direction D2 intersects the third direction D3.

Although the first conductive lower pattern 110 and the second conductive lower pattern 120 are shown as being adjacent to each other in the second direction D2, the embodiments are not limited thereto. In one variation, an additional conductive lower pattern may be disposed between the first conductive lower pattern 110 and the second conductive lower pattern 120. In addition, although a length of the first conductive lower pattern 110 in the first direction D1 is shown as being the same as a length of the second conductive lower pattern 120 in the first direction D1, the embodiments are not limited thereto.

The first interlayer insulating film 150 may cover or overlap a gate electrode and a source/drain of a transistor formed in a front-end-of-line (FEOL) process. Alternatively, the gate electrode of the transistor may be disposed inside the first interlayer insulating film 150. Alternatively, the first interlayer insulating film 150 may be an interlayer insulating film formed in a back-end-of-line (BEOL) process.

In other words, as an example, each of the first conductive lower pattern 110 and the second conductive lower pattern 120 may be a contact or a contact wiring formed in a middle-of-line (MOD) process. As another example, the first conductive lower pattern 110 and the second conductive lower pattern 120 may be connection wirings formed in the BEOL process. As yet another example, the first conductive lower pattern 110 and the second conductive lower pattern 120 may be gate electrodes formed in the FEOL process.

In the following description, the first conductive lower pattern 110 and the second conductive lower pattern 120 will be described as being connection wirings formed in the BEOL process. For example, the first conductive lower pattern 110 and the second conductive lower pattern 120 may be disposed on a first metal level.

The first interlayer insulating film 150 may include, for example, at least one of silicon oxide, silicon nitride, silicon oxynitride, and a low dielectric constant material. The low dielectric constant material may have a lower dielectric constant than silicon oxide. The low dielectric constant material may be, for example, silicon oxide having moderately high carbon and hydrogen, and may be a material such as SiCOH. On the other hand, since carbon is included in the insulating material, the dielectric constant of the insulating material may be lowered. However, in order to further lower the dielectric constant of the insulating material, the insulating material may include a pore such as a cavity in which gas or air is filled in the insulating material.

The low dielectric constant material may include, for example, but not limited to, Fluorinated TetraEthylOrthoSilicate (FTEOS), Hydrogen SilsesQuioxane (HSQ), Bis-benzoCycloButene (BCB), TetraMethylOrthoSilicate (TMOS), OctaMethyleyCloTetraSiloxane (OMCTS), HexaMethylDiSiloxane (HMDS), TriMethylSilyl Borate (TMSB), DiAcetoxyDitertiaryButoSiloxane (DADBS), TriMethylSilil Phosphate (TMSP), PolyTetraFluoroEthylene (PTFE), TOSZ (Tonen SilaZen), FSG (Fluoride Silicate Glass), polyimide nanofoams such as polypropylene oxide, CDO (Carbon Doped silicon Oxide), OSG (Organo Silicate Glass), SiLK, Amorphous Fluorinated Carbon, silica aerogels, silica xerogels, mesoporous silica or combinations thereof.

The first conductive lower pattern 110 and the second conductive lower pattern 120 may each include, for example, a lower wiring barrier film 110a and a lower wiring filling film 110b. The lower connection wiring filling film 110b may be disposed on the lower wiring barrier film 110a. The first conductive lower pattern 110 and the second conductive lower pattern 120 may each include a plurality of conductive films. The first conductive lower pattern 110 and the second conductive lower pattern 120 may each have multiple conductive film structures.

The lower wiring barrier film 110a may extend along the side wall of the lower wiring filling film 110b and the bottom surface of the lower wiring filling film 110b. In one variation, the lower wiring barrier film 110a may not be disposed on the side wall of the lower wiring filling film 110b. As another example, the lower wiring barrier film 110a may not be disposed on the bottom surface of the lower wiring filling film 110b.

The lower wiring barrier film 110a may include, for example, at least one of metal, conductive metal nitride, conductive metal carbide, conductive metal oxide, conductive metal carbonitride, and two-dimensional material (2D material). The lower wiring barrier film 110a may include, for example, but not limited to, at least one of tantalum (Ta), tantalum nitride (TaN), titanium (Ti), titanium nitride (TiN), titanium silicon nitride (TiSiN), ruthenium (Ru), cobalt (Co), nickel (Ni), nickel boron (NiB), tungsten (W), tungsten nitride (WN), tungsten carbonitride (WCN), zirconium (Zr), zirconium nitride (ZrN), vanadium (V), vanadium nitride (VN), niobium (Nb), niobium nitride (NbN), platinum (Pt), iridium (Ir), rhodium (Rh), molybdenum (Mo), and two-dimensional material,

The two-dimensional material (2D material) may include a 2D allotrope or a 2D compound, and may include, for example, but not limited to, at least one of graphene, boron nitride (BN), molybdenum sulfide, molybdenum selenide, tungsten sulfide, tungsten selenide, and tantalum sulfide. That is, since the above-mentioned 2D materials are only listed by way of example, the 2D materials that may be included in the semiconductor device of the present disclosure are not limited by the above-mentioned materials.

The lower wiring filling film 110b may include a metal or a conductive compound containing a metal. The lower wiring filling film 110a may include, for example, but not limited to, at least one of aluminum (Al), copper (Cu), tungsten (W), cobalt (Co), ruthenium (Ru), silver (Ag), gold (Au), manganese (Mn), molybdenum (Mo), rhodium (Rh), iridium (Ir), RuA1, NiA1, NbB2, MoB₂, TaB₂, V₂A1C, and CrA1C. When the lower wiring filling film 110b contains copper (Cu), the lower wiring filling film 110b may include, for example, carbon (C), silver (Ag), cobalt (Co), tantalum (Ta), indium (In), tin (Sn), zinc (Zn), manganese (Mn), titanium (Ti), magnesium (Mg), chromium (Cr), germanium (Ge), strontium (Sr), platinum (Pt), magnesium (Mg), aluminum (Al) or zirconium (Zr).

Widths of the first conductive lower pattern 110 and the second conductive lower pattern 120 in the first direction D1 may decrease as it goes away from the upper surface of the first interlayer insulating film 150. Furthermore, the widths of the first conductive lower wiring 110 and the second conductive lower wiring 120 in the second direction D2 may decrease, as it goes from the upper surface of the first interlayer insulating film 150.

In one variation, the widths of the first conductive lower pattern 110 and the second conductive lower pattern 120 in the first direction D1 may increase it goes away from the upper surface of the first interlayer insulating film 150. The widths of the first conductive lower pattern 110 and the second conductive lower pattern 120 in the second direction D2 may increase, as it goes away from the upper surface of the first interlayer insulating film 150.

Although not shown, a via pattern that connects the first conductive lower pattern 110 and a conductive pattern disposed below the first conductive lower pattern 110 may be further disposed. Similarly, a via pattern that connects the second conductive lower pattern 120 and a conductive pattern disposed below the second conductive lower pattern 120 may be further disposed.

A second interlayer insulating film 160 may be disposed on the first conductive lower pattern 110, the second conductive lower pattern 120, and the first interlayer insulating film 150. The second interlayer insulating film 160 may include, for example, at least one of silicon oxide, silicon nitride, silicon oxynitride, and a low dielectric constant material.

A first etching stop film 155 may be disposed between the first interlayer insulating film 150 and the second interlayer insulating film 160. The first etching stop film 155 may be disposed on the first conductive lower pattern 110, the second conductive lower pattern 120, and the first interlayer insulating film 150. The first etching stop film 155 may include a material having an etching selectivity with respect to the second interlayer insulating film 160.

A third interlayer insulating film 170 may be disposed on the second interlayer insulating film 160. The third interlayer insulating film 170 may include, for example, at least one of silicon oxide, silicon nitride, silicon oxynitride, and a low dielectric constant material.

In the semiconductor device according to some embodiments, the third interlayer insulating film 170 may be a single film. The third interlayer insulating film 170 may include, but is not limited to, silicon oxide.

A second etching stop film 165 may be disposed between the second interlayer insulating film 160 and the third interlayer insulating film 170. The second etching stop film 165 may be disposed on the upper surface 160US of the second interlayer insulating film. The upper surface 160US of the second interlayer insulating film may be a boundary surface between the second etching stop film 165 and the second interlayer insulating film 160. The second etching stop film 155 may include a material having an etching selectivity with respect to the second interlayer insulating film 160.

The first etching stop film 155 and the second etching stop film 165 may each include, for example, at least one of silicon nitride (SiN), silicon oxynitride (SiON), silicon oxycarbonitride (SiOCN), silicon boron nitride (SiBN), silicon oxyboron nitride (SiOBN), silicon carbonitride (SiCN), silicate oxycarbide (SiOC), aluminum oxide (AIO), aluminum nitride (AlN), aluminum oxycarbide (AlOC), and combinations thereof. Although the first etching stop film 155 and the second etching stop film 165 are each shown as being a single film, this is only for convenience of explanation, and the embodiments are not limited thereto.

In one variation, the first etching stop film 155 may include a plurality of insulating films sequentially stacked on the first interlayer insulating film 150. The second etching stop film 165 may include a plurality of insulating films sequentially stacked on the second interlayer insulating film 160.

A first upper wiring structure 210ST and a second upper wiring structure 220ST may be disposed on the first conductive lower pattern 110 and the second conductive lower pattern 120. The first upper wiring structure 210ST and the second upper wiring structure 220ST may each be disposed inside the first etching stop film 155, the second interlayer insulating film 160, the second etching stop film 165, and the third interlayer insulating film 170.

For example, the first upper wiring structure 210ST may be connected to the first conductive lower pattern 110. The second upper wiring structure 220ST may be connected to the second conductive lower pattern 120. The first upper wiring structure 210ST may include a first wiring pattern 210 and a first via pattern 215. The second upper wiring structure 220ST may include a second wiring pattern 220 and a second via pattern 225. The first wiring pattern 210 and the second wiring pattern 220 may be disposed at a second metal level higher than the first metal level.

The first wiring pattern 210 may extend in the second direction D2. The first via pattern 215 may be disposed between the first wiring pattern 210 and the first conductive lower pattern 110. The first wiring pattern 210 may be disposed on the first via pattern 215. The first via pattern 215 connects the first conductive lower pattern 110 and the first wiring pattern 210.

The second wiring pattern 220 may extend in the second direction D2. The second wiring pattern 220 may be spaced apart from the first wiring pattern 210 in the first direction D1. Although not shown, the second via pattern 225 may be disposed between the second wiring pattern 220 and the second conductive lower pattern 120. The second wiring pattern 220 may be disposed on the second via pattern 225. The second via pattern 225 connects the second conductive lower pattern 120 and the second wiring pattern 210.

The structure of the second upper wiring structure 220ST may be substantially the same as the structure of the first upper wiring structure 210ST. The following description may be made focusing on the first wiring pattern 210 and the first via pattern 215 included in the first upper wiring structure 210ST. The contents of the second wiring pattern 220 may be substantially the same as the description of the first wiring pattern 210 below. The contents of the second via pattern 225 may be substantially the same as the description of the first via pattern 215 below.

The first via pattern 215 may be disposed on the first conductive lower pattern 110. The first via pattern 215 may be disposed inside the first etching stop film 155 and the second interlayer insulating film 160. The first via pattern 215 passes through or extends into the first etching stop film 155, and may be electrically connected to the first conductive lower pattern 110.

The first via pattern 215 may include an upper surface 215US and a bottom surface that are opposite to each other in the third direction D3. The bottom surface of the first via pattern 215 faces the first conductive lower pattern 110.

In the semiconductor device according to some embodiments, the upper surface 215US of the first via pattern may be lower than the upper surface 160US of the second interlayer insulating film on the basis of the upper surface of the first conductive lower pattern 110. The distance between the upper surface of the first conductive lower pattern 110 and the upper surface 215US of the first via pattern may be smaller than the distance between the upper surface of the first conductive lower pattern 110 and the upper surface 160US of the second interlayer insulating film.

For example, the first via pattern 215 may have a single film structure. The first via pattern 215 may not be a multiple film structure including different materials from each other like the first conductive lower pattern 110 of FIGS. 2 and 3. The first via pattern 215 may be formed of one conductive material. The first via pattern 215 may have a single conductive film structure.

The first via pattern 215 may include metal. The first via pattern 215 may include, for example, one of tungsten (W), molybdenum (Mo), cobalt (Co), and ruthenium (Ru). For example, when the first via pattern 215 includes molybdenum (Mo), the first via pattern 215 may have a single film structure formed of molybdenum. Here, the single film structure formed of molybdenum does not mean a structure formed only of molybdenum. While the first via pattern 215 including molybdenum is being formed, various impurities may flow into the first via pattern 215. That is, impurities may be included in a single film structure formed of molybdenum.

The first wiring pattern 210 may be disposed on the first via pattern 215 and the second interlayer insulating film 160. The first wiring pattern 210 is connected to the upper surface 215US of the first via pattern.

The first wiring pattern 210 may be disposed inside the second etching stop film 165 and the third interlayer insulating film 170. A part of the first wiring pattern 210 may enter the second interlayer insulating film 160. The first wiring pattern 210 may be in contact with the third interlayer insulating film 170. The first wiring pattern 210 may be in contact with the upper surface 160US of the second interlayer insulating film.

The first wiring pattern 210 may include a first lower metal wiring line 210BM and a first upper metal wiring line 210UM stacked in the third direction D3. The first lower metal wiring line 210BM and the first upper metal wiring line 210UM may each extend in the second direction D2.

The first lower metal wiring line 210BM may be disposed between the first upper metal wiring line 210UM and the first via pattern 215. The first lower metal wiring line 210BM may be disposed on the upper surface 215US of the first via pattern and the upper surface 160US of the second interlayer insulating film.

The first lower metal wiring line 210BM may be in contact with the upper surface 215US of the first via pattern. The first lower metal wiring line 210BM may be in contact with the upper surface 160US of the second interlayer insulating film. Since the upper surface 215US of the first via pattern is lower in the third direction D3 than the upper surface 160US of the second interlayer insulating film, a part of the first lower metal wiring line 210BM may enter or extend into the second interlayer insulating film 160.

The first upper metal wiring line 210UM may be disposed on the first lower metal wiring line 210BM. The first upper metal wiring line 210UM may be disposed inside the third interlayer insulating film 170.

The first upper metal wiring line 210UM includes an upper surface 210UM_US and a bottom surface 210UM_BS that are opposite to each other in the third direction D3. The bottom surface 210UM_BS of the first upper metal wiring line may face the first via pattern 215. The first lower metal wiring line 210BM may be disposed between the upper surface 215US of the first via pattern and the bottom surface 210UM_BS of the first upper metal wiring line.

A width W12 of the bottom surface 210UM_BS of the first upper metal wiring line in the first direction D1 may differ from a width W11 of the upper surface 210UM_US of the first upper metal wiring line in the first direction D1. For example, the width W12 of the bottom surface 210UM_BS of the first upper metal wiring line in the first direction D1 may be smaller than the width W11 of the upper surface 210UM_US of the first upper metal wiring line in the first direction D1.

Although the upper surface 210UM_US of the first upper metal wiring line is shown as being a plane, this is only for convenience of explanation, and the embodiments are not limited thereto. In one variation, the upper surface 210UM_US of the first upper metal wiring line may include a convex curved surface.

The first wiring pattern 210 may include a side wall 210SW extending in the third direction D3. The side wall 210SW of the first wiring pattern may be defined by the first lower metal wiring line 210BM and the first upper metal wiring line 210UM. The side wall 210SW of the first wiring pattern may include a side wall 210UM_S of the first upper metal wiring line, and a side wall 210BM_S of the first lower metal wiring line. The side wall 210UM_S of the first upper metal wiring line connects the bottom surface 210UM_BS of the first upper metal wiring line and the upper surface 210UM_US of the first upper metal wiring line.

In the semiconductor device according to some embodiments, the first lower metal wiring line 210BM may extend along the bottom surface 210UM_BS of the first upper metal wiring line. The first lower metal wiring line 210BM does not extend along the side wall 210UM_S of the first upper metal wiring line.

The third interlayer insulating film 170 may be in contact with the first upper metal wiring line 210UM. For example, the third interlayer insulating film 170 may be in contact with the side wall 210UM_S of the first upper metal wiring line. Although not shown, a metal oxide which is in an oxidized form of metal contained in the first upper metal wiring line 210UM may be disposed along the boundary between the third interlayer insulating film 170 and the first upper metal wiring line 210UM.

The first lower metal wiring line 210BM and the first upper metal wiring line 210UM may each have a single conductive film structure. The first lower metal wiring line 210BM and the first upper metal wiring line 210UM may each include metal. The first lower metal wiring line 210BM may include a metal different from the first upper metal wiring line 210UM. The first lower metal wiring line 210BM may include a different metal from the first via pattern 215 having a single conductive film structure.

The first lower metal wiring line 210BM and the first upper metal wiring line 210UM may each include, for example, one of tungsten (W), molybdenum (Mo), cobalt (Co), and ruthenium (Ru). As an example, the first lower metal wiring line 210BM may include one of tungsten (W), cobalt (Co), and ruthenium (Ru), and the first upper metal wiring line 210UM may include molybdenum (Mo), but the embodiments are not limited thereto.

In the semiconductor device according to some embodiments, a thickness t11 of a first lower metal wiring line 210BM on the upper surface 215US of the first via pattern may be different from a thickness t12 of the first lower metal wiring line 210BM on the upper surface 160US of the second interlayer insulating film. For example, the thickness t11 of the first lower metal wiring line 210BM on the upper surface 215US of the first via pattern may be greater than the thickness t12 of the first lower metal wiring line 210BM on the upper surface 160US of the second interlayer insulating film.

In other words, the first wiring pattern 210 may include a first portion 210P1 and a second portion 210P2. The first portion 210P1 of the first wiring pattern may overlap the upper surface 215US of the first via pattern in the third direction D3. The second portion 210P2 of the first wiring pattern does not overlap the upper surface 215US of the first via pattern in the third direction D3.

The thickness t11 of the first lower metal wiring line 210BM in the first portion 210P1 of the first wiring pattern may differ from the thickness t12 of the first lower metal wiring line 210BM in the second portion 210P2 of the first wiring pattern. The thickness t11 of the first lower metal wiring line 210BM in the first portion 210P1 of the first wiring pattern may be greater than the thickness t12 of the first lower metal wiring line 210BM in the second portion 210P2 of the first wiring pattern.

During formation of the first lower metal wiring line 210BM, the thickness of the first lower metal wiring line 210BM may vary depending on which material the first lower metal wiring line 210BM is formed on. It is assumed that the first lower metal wiring line 210BM may include ruthenium (Ru). While the first lower metal wiring line 210BM is being formed, the thickness of the ruthenium film formed on the upper surface 215US of the first via pattern may differ from the thickness of the ruthenium film formed on the upper surface 160US of the second interlayer insulating film.

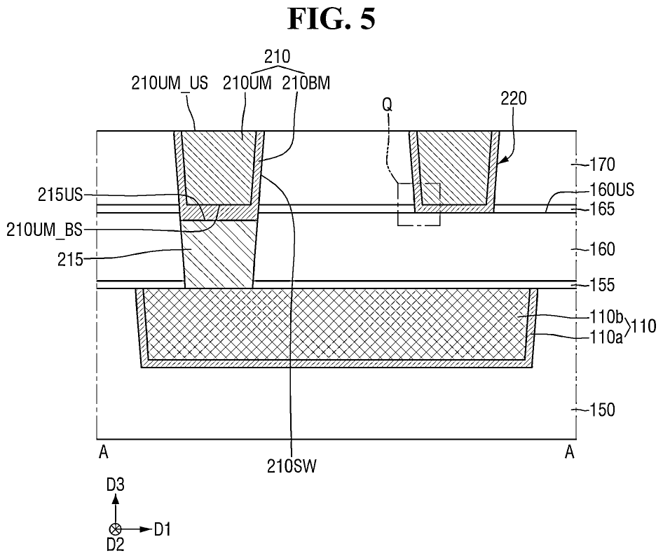

FIGS. 5 to 7 are diagrams of a semiconductor device according to some embodiments. For convenience of explanation, the explanation will focus on the points that are different from those explained using FIGS. 1 to 4.

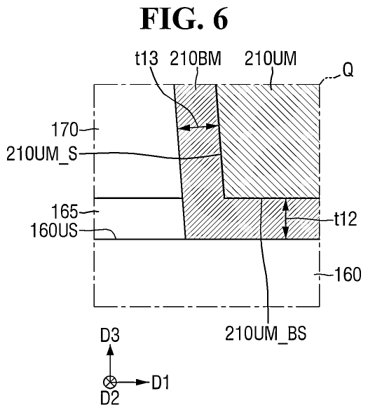

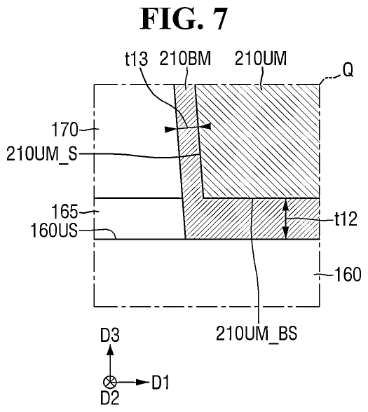

For reference, FIGS. 6 and 7 are enlarged views of a portion Q of FIG. 5.

Referring to FIGS. 5 to 7, in the semiconductor device according to some embodiments, the first lower metal wiring line 210BM may extend along the bottom surface 210UM_BS of the first upper metal wiring line and the side wall 210UM_S of the first upper metal wiring line.

For example, the first lower metal wiring line 210BM may extend up to the upper surface 210UM_US of the first upper metal wiring line. The side wall 210SW of the first wiring pattern may be defined by the first lower metal wiring line 210BM.

In FIG. 6, the thickness t12 of the first lower metal wiring line 210BM between the bottom surface 210UM_BS of the first upper metal wiring line and the upper surface 160US of the second interlayer insulating film may be equal to a thickness t13 of the first lower metal wiring line 210BM on the side wall 210UM_S of the first upper metal wiring line.

In FIG. 7, the thickness t12 of the first lower metal wiring line 210BM between the bottom surface 210UM_BS of the first upper metal wiring line and the upper surface 160US of the second interlayer insulating film may be greater than the thickness t13 of the first lower metal wiring line 210BM on the side wall 210UM_S of the first upper metal wiring line.

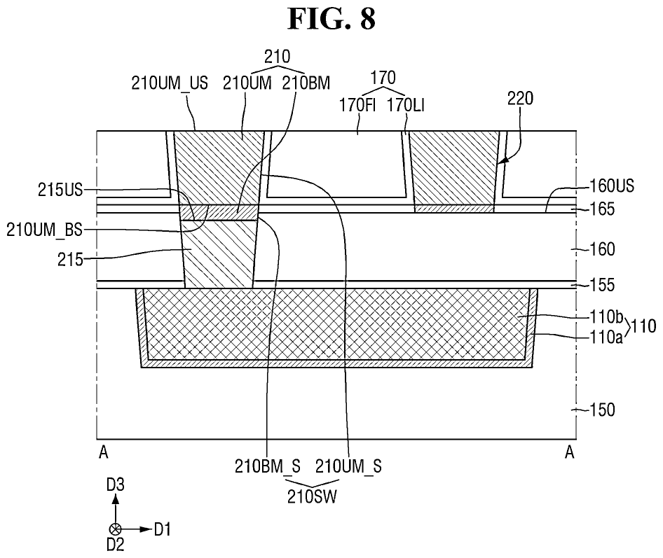

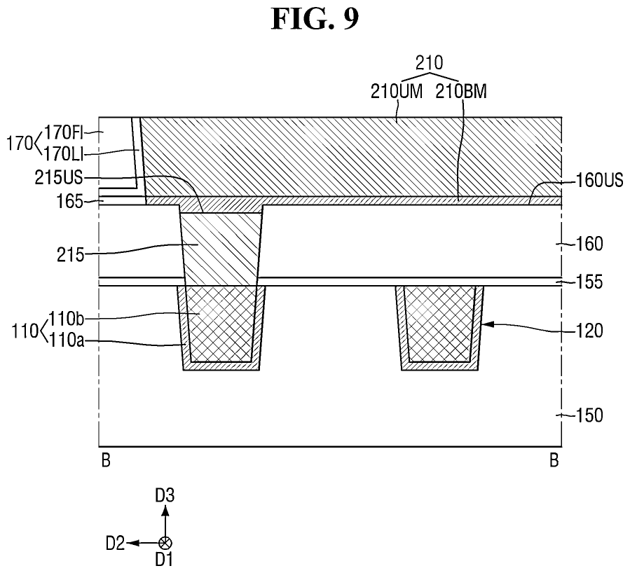

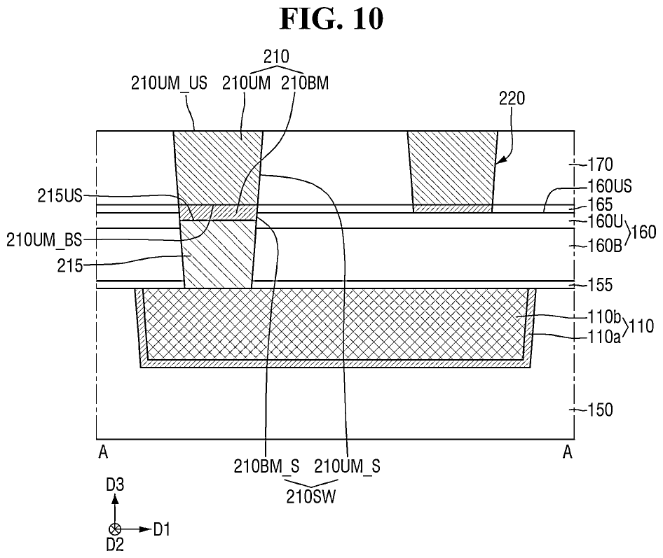

FIGS. 8 and 9 are diagrams of a semiconductor device according to some embodiments. FIG. 10 is a diagram of the semiconductor device according to some embodiments. For convenience of explanation, the explanation will focus on the points that are different from those explained using FIGS. 1 to 4.

Referring to FIGS. 8 and 9, in the semiconductor device according to some embodiments, the third interlayer insulating film 170 may include a wiring insulating liner 170LI and a filling interlayer insulating film 170FI.

The wiring insulating liner 170LI may be disposed on the second etching stop film 165. The wiring insulating liner 170LI may extend along the upper surface 160US of the second interlayer insulating film and the side wall 210SW of the first wiring pattern. The wiring insulating liner 170LI may extend along the side wall 210UM_S of the first upper metal wiring line. A second etching stop film 165 may be disposed between the wiring insulating liner 170LI and the second interlayer insulating film 160.

The filling interlayer insulating film 170FI may be disposed on the wiring insulating liner 170LI. The filling interlayer insulating film 170FI may fill or be in a space defined by the wiring insulating liner 170LI.

The wiring insulating liner 170LI may include, for example, but are not limited to, one of silicon nitride (SiN), silicon oxynitride (SiON), silicon oxycarbonitride (SiOCN), silicon boron nitride (SiBN), silicon oxyboron nitride (SiOBN), silicon carbonitride (SiCN), and silicate oxycarbide (SiOC). The filling interlayer insulating film 170FI may include, for example, at least one of silicon oxide, silicon nitride, silicon oxynitride, and a low dielectric constant material.

Referring to FIG. 10, in the semiconductor device according to some embodiments, the second interlayer insulating film 160 may include a second lower interlayer insulating film 160B and a second upper interlayer insulating film 160U.

The second upper interlayer insulating film 160U may be disposed on the second lower interlayer insulating film 160B. The second upper interlayer insulating film 160U may be disposed between the second lower interlayer insulating film 160B and the second etching stop film 165. The second upper interlayer insulating film 160U may include an upper surface 160US of the second interlayer insulating film.

For example, the first lower metal wiring line 210BM may be in contact with the second upper interlayer insulating film 160U.

The second lower interlayer insulating film 160B may include, for example, a low dielectric constant material. The second upper interlayer insulating film 160U may include, for example, at least one of silicon oxide and aluminum oxide.

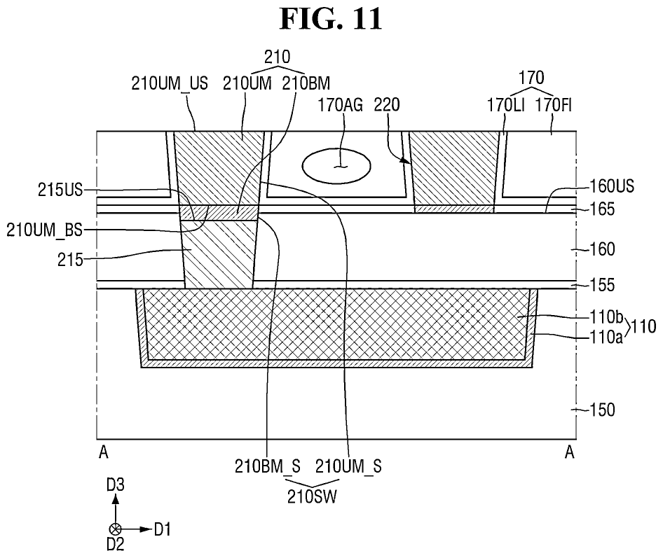

FIG. 11 is a diagram of a semiconductor device according to some embodiments. For convenience of explanation, points different from those described using FIGS. 1 to 4, 8, and 9 will be mainly explained.

Referring to FIG. 11, in the semiconductor device according to some embodiments, the third interlayer insulating film 170 may include an inter-wiring air gap 170AG.

The inter-wiring air gap 170AG may be disposed between the first wiring pattern 210 and the second wiring pattern 220 that are adjacent to each other in the first direction D1. For example, the filling interlayer insulating film 170FI may include the inter-wiring air gap 170AG.

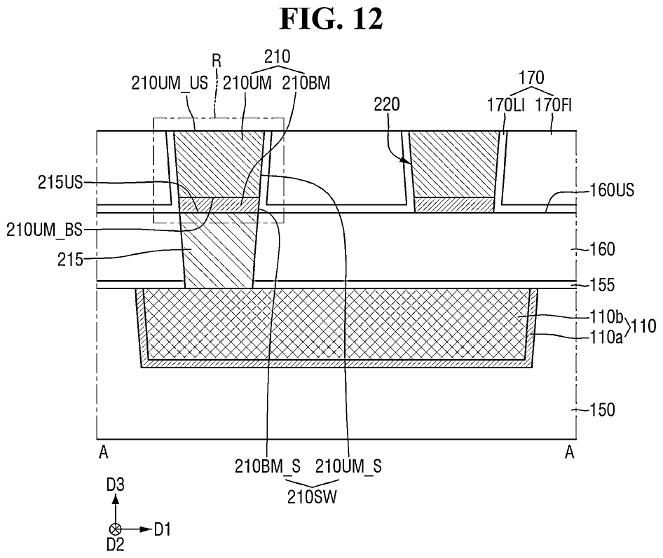

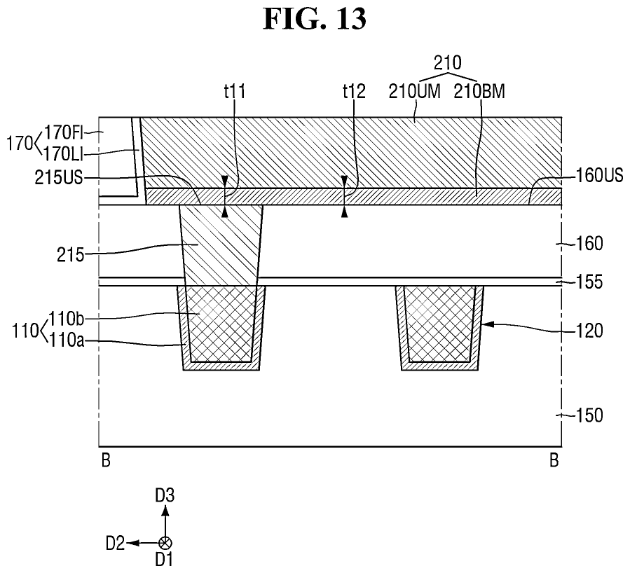

FIGS. 12 to 14 are diagrams for explaining a semiconductor device according to some embodiments. For convenience of explanation, the explanation will focus on the points that are different from those explained using FIGS. 1 to 4.

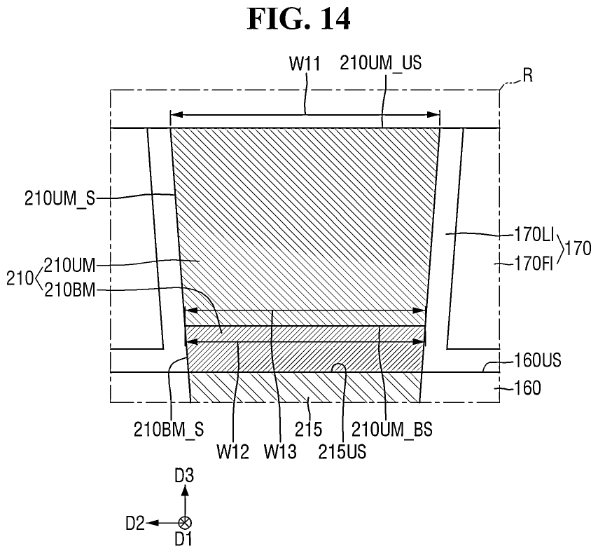

For reference, FIG. 14 is an enlarged view of a portion R of FIG. 12.

Referring to FIGS. 12 to 14, in the semiconductor device according to some embodiments, a distance between the upper surface of the first conductive lower pattern 110 and the upper surface 215US of the first via pattern may be substantially the same as a distance between the upper surface of the first conductive lower pattern 110 and the upper surface 160US of the second interlayer insulating film.

Based on the upper surface of the first conductive lower pattern 110, the upper surface 215US of the first via pattern may not be lower than the upper surface 160US of the second interlayer insulating film.

For example, the thickness t11 of the first lower metal wiring line 210BM on the upper surface 215US of the first via pattern may be the same as the thickness t12 of the first lower metal wiring line 210BM on the upper surface 160US of the second interlayer insulating film. Here, the meaning of “same thickness” includes not only a case where the thickness is exactly the same at the two positions being compared, but also includes minute differences in thickness that may occur due to process margins, etc.

In some embodiments, the second etching stop film (165 of FIGS. 2 and 3) is not disposed between the second interlayer insulating film 160 and the third interlayer insulating film 170. The third interlayer insulating film 170 may be in contact with the upper surface 160US of the second interlayer insulating film.

The third interlayer insulating film 170 may include a wiring insulating liner 170LI and a filling interlayer insulating film 170FI. The wiring insulating liner 170LI may extend along the upper surface 160US of the second interlayer insulating film and the side wall 210SW of the first wiring pattern. The wiring insulating liner 170LI may be in contact with the upper surface 160US of the second interlayer insulating film. The filling interlayer insulating film 170FI may be disposed on the wiring insulating liner 170LI.

In one variation, the filling interlayer insulating film 170FI may include an inter-wiring air gap 170AG as shown in FIG. 11.

A width W13 of the first lower metal wiring line 210BM in the first direction D1 may be the same as a width W12 of the bottom surface 210UM_BS of the first upper metal wiring line in the first direction D1. For example, the width W13 of the first lower metal wiring line 210BM in the first direction D1 may be a width of the first lower metal wiring line 210BM that borders or at least partially surrounds the first upper metal wiring line 210UM. In other words, the width W13 of the first lower metal wiring line 210BM in the first direction D1 may be a width of the boundary surface of the first lower metal wiring line 210BM that is in contact with the bottom surface 210UM_BS of the first upper metal wiring line.

The width W11 of the first upper metal wiring line 210UM_US in the first direction D1 may be greater than the width W13 of the first lower metal wiring line 210BM in the first direction D1.

The first lower metal wiring line 210BM may include a bottom surface that faces the first via pattern 215. Although the width of the bottom surface of the first lower metal wiring line 210BM in the first direction D1 is shown as being equal to the width of the upper surface 215US of the first via pattern in the first direction D1, the embodiments are not limited thereto.

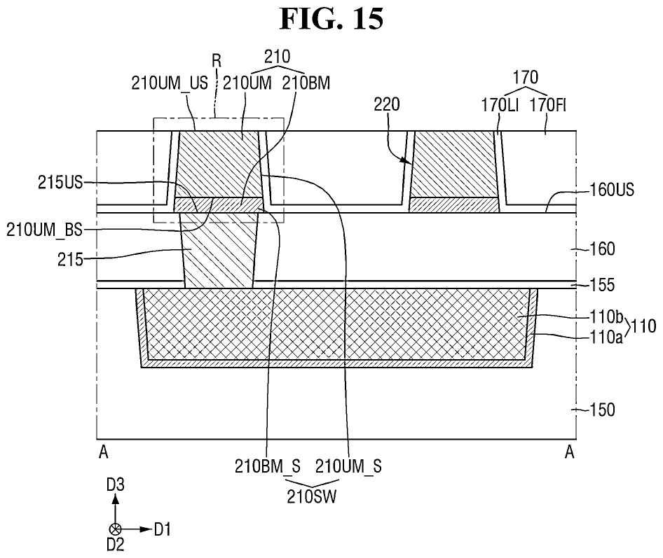

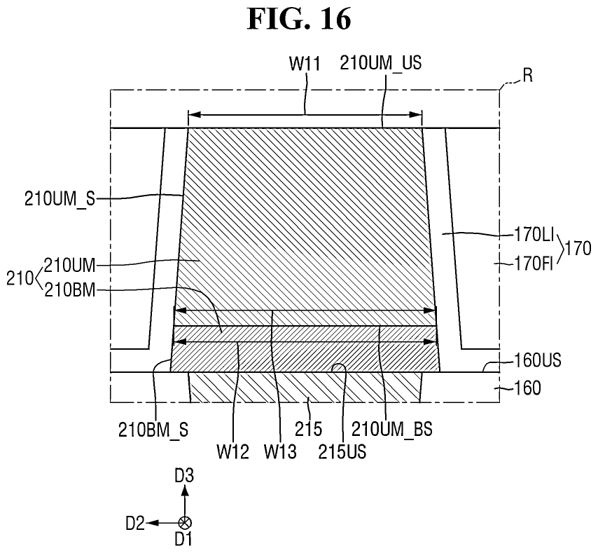

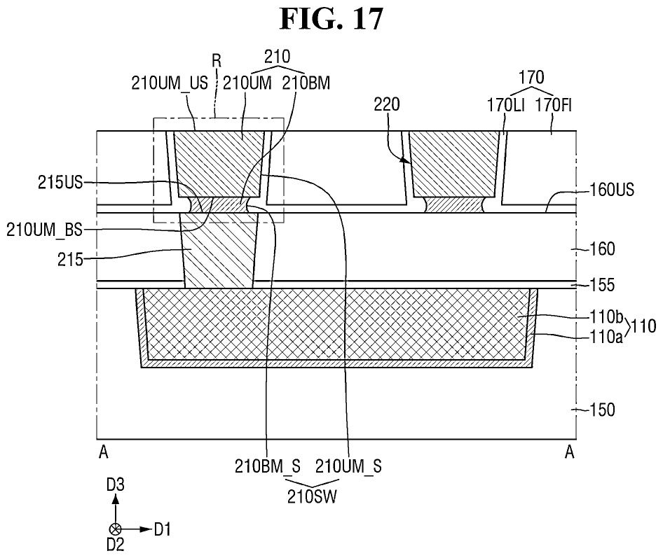

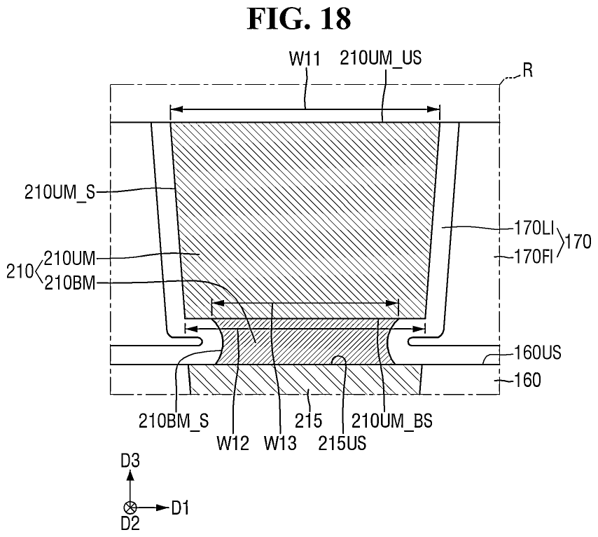

FIGS. 15 and 16 are diagrams of a semiconductor device according to some embodiments. FIGS. 17 and 18 are diagrams of a semiconductor device according to some embodiments. For convenience of explanation, the explanation will focus on the points that are different from those explained using FIGS. 12 to 14.

For reference, FIGS. 16 and 18 are enlarged views of a portion R of FIGS. 15 and 17.

Referring to FIGS. 15 and 16, in the semiconductor device according to some embodiments, the width W11 of the upper surface 210UM_US of the first upper metal wiring line in the first direction D1 may be smaller than the width W12 of the bottom surface 210UM_BS of the first upper metal wiring line in the first direction D1.

The width W11 of the first upper metal wiring line 210UM_US in the first direction D1 may be smaller than the width W13 of the first lower metal wiring line 210BM in the first direction D1.

Although the width of the bottom surface of the first lower metal wiring line 210BM in the first direction D1 is shown as being greater than the width of the upper surface 215US of the first via pattern in the first direction D1, the embodiments are not limited thereto.

Referring to FIGS. 17 and 18, in the semiconductor device according to some embodiments, the width W13 of the first lower metal wiring line 210BM in the first direction D1 is smaller than the width W12 of the bottom surface 210UM_BS of the first upper metal wiring line in the first direction D.

The first lower metal wiring line 210BM may be undercut or recessed below the first upper metal wiring line 210UM. A part of the bottom surface 210UM_BS of the first upper metal wiring line may be in contact with the wiring insulating liner 170LI.

In the first wiring pattern 210 as shown in FIGS. 15 and 16, the first lower metal wiring line 210BM may be undercut or recessed below the first upper metal wiring line 210UM.

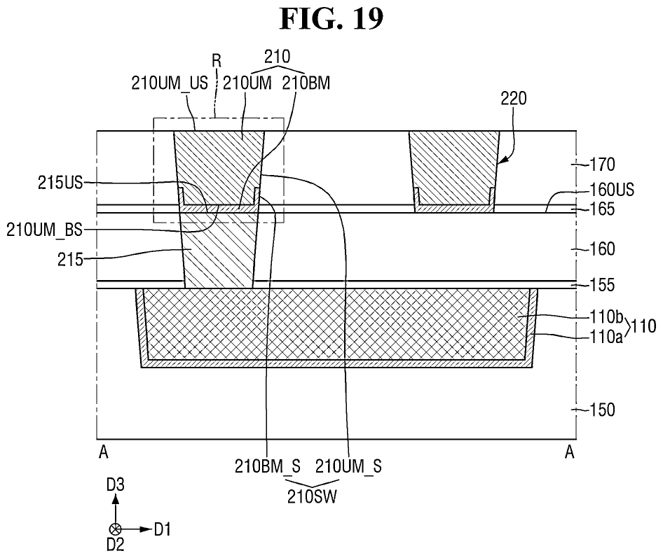

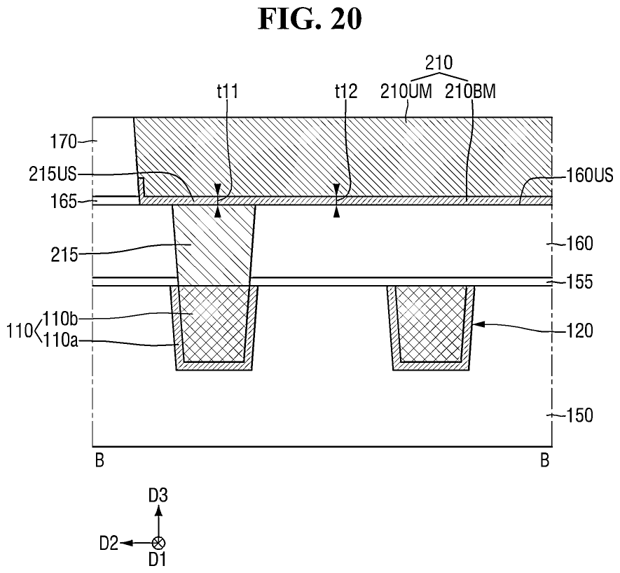

FIGS. 19 to 22 are diagrams of a semiconductor device according to some embodiments. For convenience of explanation, the explanation will focus on the points that are different from those explained using FIGS. 1 to 4.

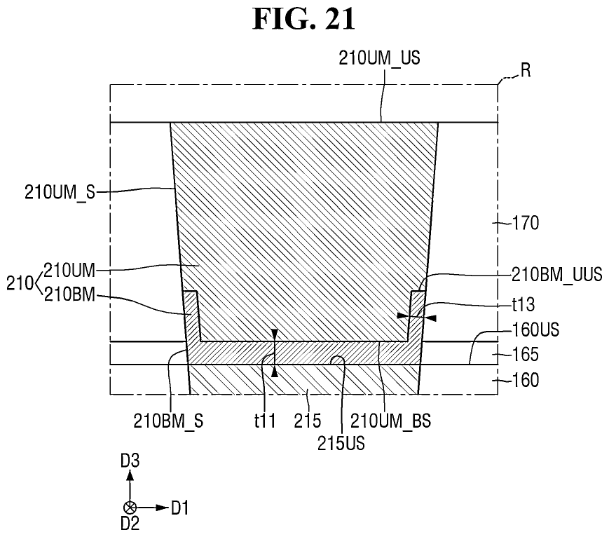

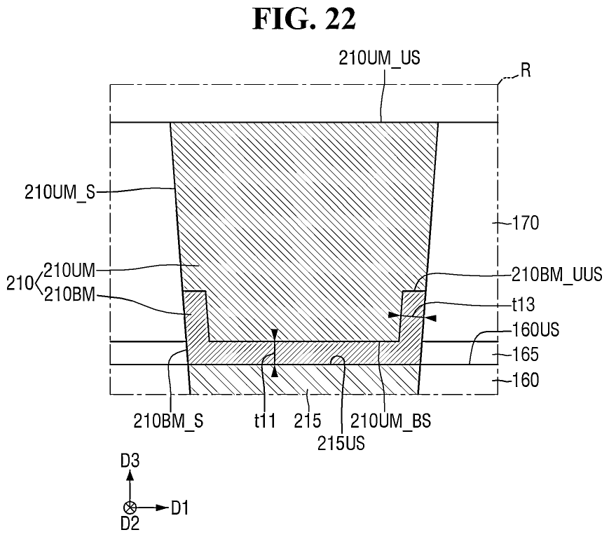

For reference, FIGS. 21 and 22 are enlarged views of a portion R of FIG. 19.

Referring to FIGS. 19 to 22, in the semiconductor device according to some embodiments, the first lower metal wiring line 210BM may extend along a part of the side wall 210UM_S of the first upper metal wiring line.

The first lower metal wiring line 210BM does not extend up to the upper surface 210UM_US of the first upper metal wiring line. The side wall 210SW of the first wiring pattern may be defined by the first lower metal wiring line 210BM and the first upper metal wiring line 210UM.

The first upper metal wiring line 210UM covers or overlaps the uppermost surface 210BM_UUS of the first lower metal wiring line. The first upper metal wiring line 210UM may be in contact with the uppermost surface 210BM_UUS of the first lower metal wiring line.

A distance between the upper surface of the first conductive lower pattern 110 and the upper surface 215US of the first via pattern may be substantially equal to a distance between the upper surface of the first conductive lower pattern 110 and the upper surface 160US of the second interlayer insulating film. Based on the upper surface of the first conductive lower pattern 110, the upper surface 215US of the first via pattern may not be lower than the upper surface 160US of the second interlayer insulating film in the third direction.

For example, the thickness t11 of the first lower metal wiring line 210BM on the upper surface 215US of the first via pattern may be the same as the thickness t12 of the first lower metal wiring line 210BM on the upper surface 160US of the second interlayer insulating film.

In FIG. 21, the thickness t11 of the first lower metal wiring line 210BM between the bottom surface 210UM_BS of the first upper metal wiring line and the upper surface 2150US of the first via pattern may be greater than the thickness t13 of the first lower metal wiring line 210BM on the side wall 210UM_S of the first upper metal wiring line.

In FIG. 22, the thickness t11 of the first lower metal wiring line 210BM on the bottom surface 210UM_BS of the first upper metal wiring line may be the same as the thickness t13 of the first lower metal wiring line 210BM on the side wall 210UM_S of the first upper metal wiring line.

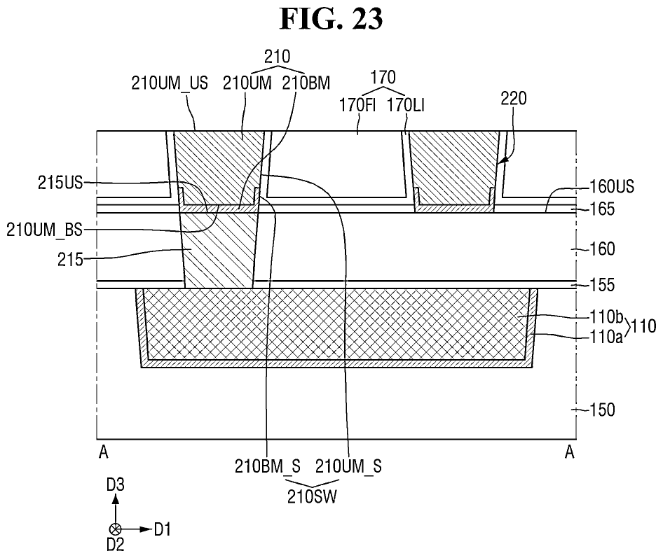

FIG. 23 is a diagram of a semiconductor device according to some embodiments. For convenience of explanation, points different from those described using FIGS. 19 to 22 will be mainly explained.

Referring to FIG. 23, in the semiconductor device according to some embodiments, the third interlayer insulating film 170 may include a wiring insulating liner 170LI and a filling interlayer insulating film 170FI.

The wiring insulating liner 170LI may extend along the upper surface 160US of the second interlayer insulating film and the side wall 210SW of the first wiring pattern. The wiring insulating liner 170LI may be in contact with the second etching stop film 165. The filling interlayer insulating film 170FI may be disposed on the wiring insulating liner 170LI.

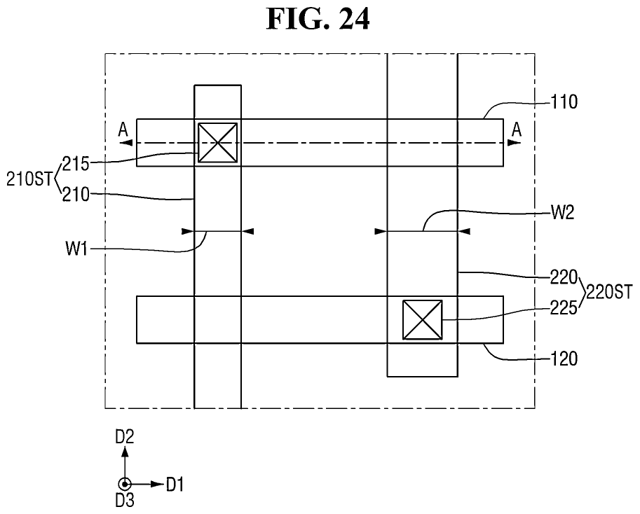

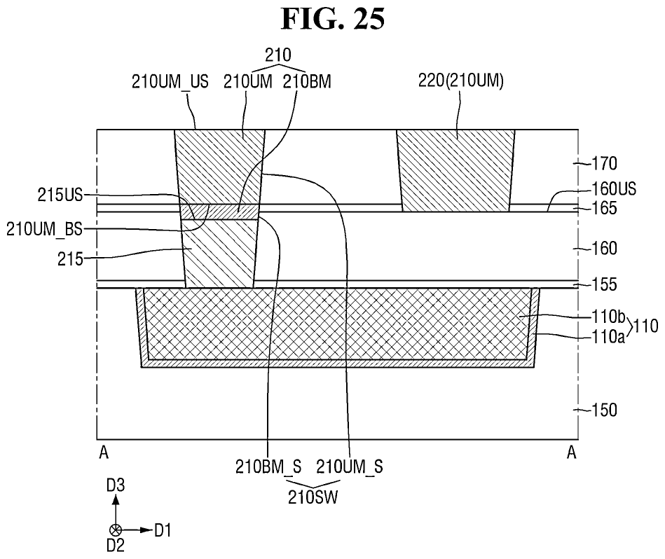

FIGS. 24 and 25 are diagrams of a semiconductor device according to some embodiments. For convenience of explanation, the explanation will focus on the points that are different from those explained using FIGS. 1 to 4.

Referring to FIGS. 24 and 25, in the semiconductor device according to some embodiments, the width W1 of the first wiring pattern 210 in the first direction D1 may be smaller than the width W2 of the second wiring pattern 220 in the first direction D1.

The first wiring pattern 210 will be described as an example. The width W1 of the first wiring pattern 210 in the first direction D1 may be a width of the upper surface of the first wiring pattern 210 in the first direction D1.

The first wiring pattern 210 may include a first lower metal wiring line 210BM and a first upper metal wiring line 210UM. The second wiring pattern 220 may include only the first upper metal wiring line 210UM without the first lower metal wiring line 210BM. When the first wiring pattern 210 and the second wiring pattern 220 have different widths, the first wiring pattern 210 and the second wiring pattern 220 may have metal stacked structures different from each other.

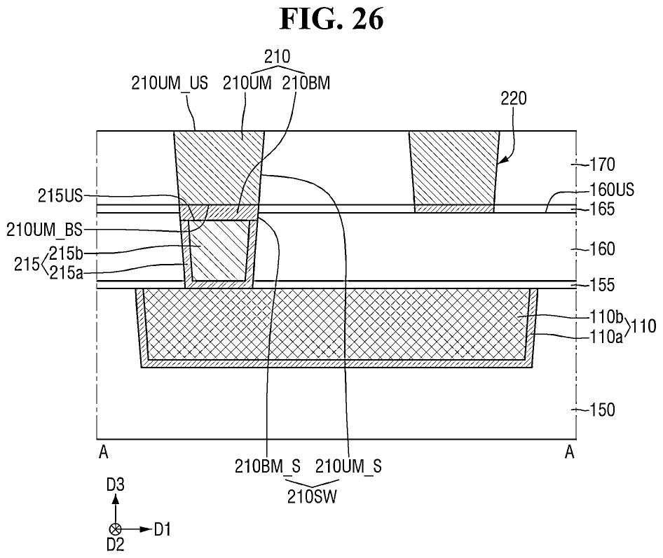

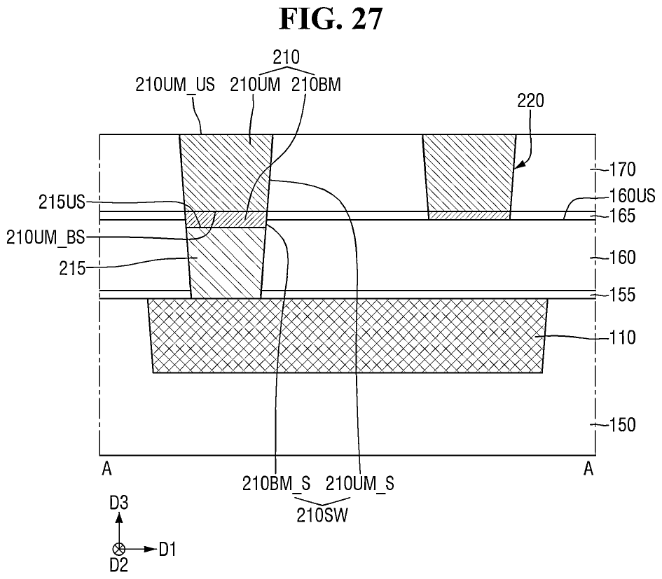

FIGS. 26 and 27 are diagrams of a semiconductor device according to some embodiments, respectively. For convenience of explanation, the explanation will focus on the points that are different from those explained using FIGS. 1 to 4.

Referring to FIG. 26, in the semiconductor device according to some embodiments, the first via pattern 215 may include a via barrier film 215a and a via filling film 215b.

The via filling film 215b may be disposed on the via barrier film 215a. The via barrier film 215a may extend along the side wall and bottom surface of the via filling film 215b. The first via pattern 215 may have multiple conductive film structures. The upper surface 215 of the first via pattern may be defined by the via barrier film 215a and the via filling film 215b.

The description of the materials that may be included in the via barrier film 215a and the via filling film 215b may be substantially the same as the description of the lower wiring barrier film 110a and the lower wiring filling film 110b.

Referring to FIG. 27, in the semiconductor device according to some embodiments, the first conductive lower pattern 110 may have a single film structure.

For example, the first conductive lower pattern 110 may have a single conductive film structure. The first conductive lower pattern 110 may include, for example, one of a metal, a conductive metal nitride, a conductive metal carbide, a conductive metal oxide, and a conductive metal carbonitride.

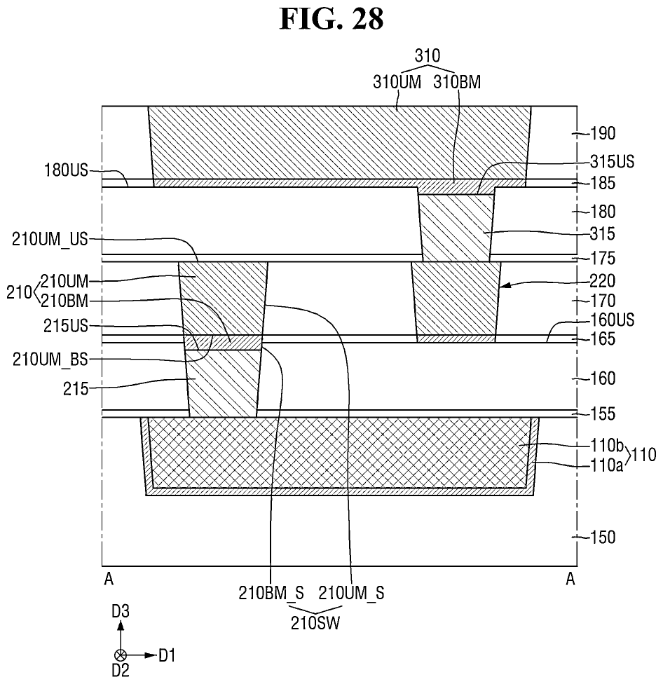

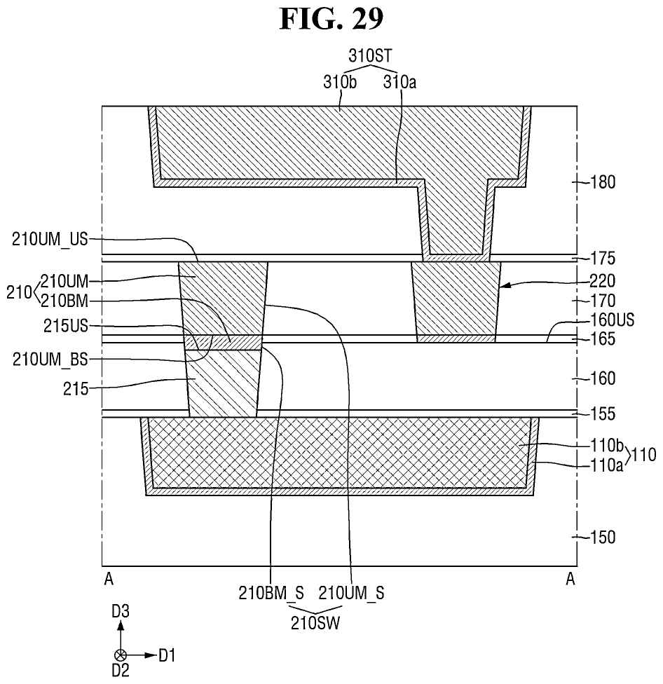

FIGS. 28 and 29 are diagrams of a semiconductor device according to some embodiments, respectively. For convenience of explanation, the explanation will focus on the points that are different from those explained using FIGS. 1 to 4.

For reference, in FIGS. 28 and 29, although the structures of the first wiring pattern 210 and the first via pattern 215 are shown as being the same as those shown in FIGS. 2 and 3, the structures are not limited thereto. The structures of the first wiring pattern 210, the first via pattern 215, and the first conductive lower pattern 110 may be one of the structures described using FIGS. 1 to 27.

Referring to FIG. 28, the semiconductor device according to some embodiments may further include a third wiring pattern 310 and a third via pattern 315.

The third etching stop film 175, the fourth interlayer insulating film 180, the fourth etching stop film 185, and the fifth interlayer insulating film 190 may be disposed sequentially on the third interlayer insulating film 170, the first wiring pattern 210, and the second wiring pattern 220. The third etching stop film 175 may be disposed between the third interlayer insulating film 170 and the fourth interlayer insulating film 180. The fourth etching stop film 185 may be disposed between the fourth interlayer insulating film 180 and the fifth interlayer insulating film 190.

The third via pattern 315 may be connected to the second wiring pattern 220 on the second wiring pattern 220. The third via pattern 315 may be disposed inside the third etching stop film 175 and the fourth interlayer insulating film 180. In one variation, the third via pattern 315 may be connected to the first wiring pattern 210 on the first wiring pattern 210.

With the upper surface of the second wiring pattern 220 as a reference, the upper surface 315US of the third via pattern may be lower than the upper surface 180US of the fourth interlayer insulating film.

The third wiring pattern 310 may be disposed on the third via pattern 315 and the fourth interlayer insulating film 180. The third wiring pattern 310 is connected to the upper surface 315US of the third via pattern. The third wiring pattern 310 may be disposed inside the fourth etching stop film 145 and the fifth interlayer insulating film 190.

The third wiring pattern 310 may include a second lower metal wiring line 310BM and a second upper metal wiring line 310UM that are stacked in the third direction D3. The second lower metal wiring line 310BM and the second upper metal wiring line 310UM may each extend in the first direction D1.

The description of the third wiring pattern 310 and the third via pattern 315 may be similar to the description of the first wiring pattern 210 and the first via pattern 215 described using FIGS. 1 to 4. Since the description of the first wiring pattern 210 and the first via pattern 215 may be applied to the third wiring pattern 310 and the third via pattern 315, the description thereof will not be provided below.

In addition, although the structures of the third wiring pattern 310 and the third via pattern 315 are shown as being the same as the structures of the first wiring pattern 210 and the first via pattern 215 described using FIGS. 1 to 4, the embodiments are not limited thereto. In one variation, the structures of the third wiring pattern 310 and the third via pattern 315 may be the same as one of the structures of the first wiring pattern 210 and the first via pattern 215 described using FIGS. 5 to 25

Referring to FIG. 29, the semiconductor device according to some embodiments may further include a third upper wiring structure 310ST connected to the second wiring pattern 220.

The third etching stop film 175 and the fourth interlayer insulating film 180 may be sequentially disposed on the third interlayer insulating film 170, the first wiring pattern 210, and the second wiring pattern 220.

The third upper wiring structure 310ST may include a wiring line portion extending in the first direction D1, and a via portion that connects the wiring line portion and the second wiring pattern 220.

The third upper wiring structure 310ST may include an upper wiring barrier film 310a and an upper wiring filling film 310b. The upper wiring filling film 310b may be disposed on the upper wiring barrier film 310a. The via portion of the third upper wiring structure 310ST may include a part of the upper wiring barrier film 310a and a part of the upper wiring filling film 310b. The wiring line portion of the third upper wiring structure 310ST may include the remainder of the upper wiring barrier film 310a and the remainder of the upper wiring filling film 310b.

The description of materials that may be included in the upper wiring barrier film 310a and the upper wiring filling film 310b may be substantially the same as the description of the lower wiring barrier film 110a and the lower wiring filling film 110b.

In one variation, the third upper wiring structure 310ST may be connected to the first wiring pattern 210 on the first wiring pattern 210.

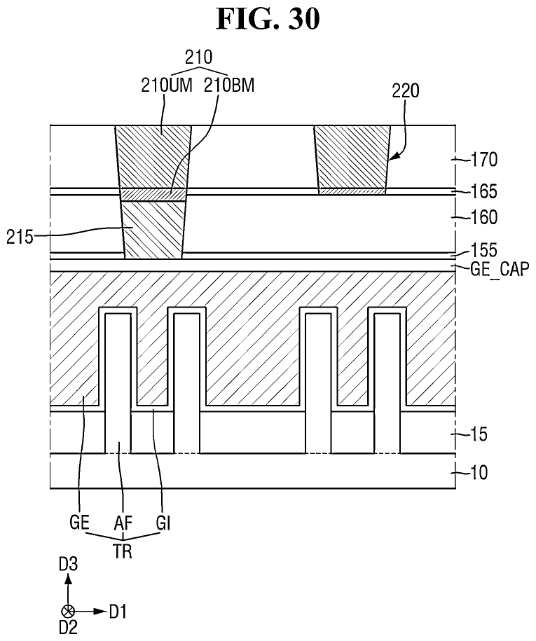

FIG. 30 is a diagram of a semiconductor device according to some embodiments.

For reference, FIG. 30 shows an example diagram taken along the first gate electrode GE. Further, in FIG. 30, the first gate electrode GE may extend in the first direction D1 as described in FIGS. 1 to 25, or may extend in the second direction D2. When the first gate electrode GE extends in the second direction D2, the fin-shaped pattern AF extends in the first direction D1 that intersects the first gate electrode GE.

Referring to FIG. 30, the semiconductor device according to some embodiments may include a transistor TR disposed between the substrate 10 and the first via pattern 215.

The substrate 10 may be a silicon substrate or silicon-on-insulator (SOI). In contrast, the substrate 10 may include, but not limited to, silicon germanium, silicon germanium on insulator (SGOI), indium antimonide, lead telluride, indium arsenide, indium phosphide, gallium arsenide, or gallium antimonide.

The transistor TR has the fin-shaped pattern AF, a first gate electrode GE on the fin-shaped pattern AF, and the first gate insulating film GI between the fin-shaped pattern AF1 and the first gate electrode GE.

Although not shown, the transistor TR may include source/drain patterns disposed on both sides of the first gate electrode GE.

The fin-shaped pattern AF may protrude or extend from the substrate 10. The fin-shaped pattern AF may extend long in one direction. The fin-shaped pattern AF1 may be a part of the substrate 10, and may include an epitaxial layer grown from the substrate 10. The fin-shaped pattern AF may include, for example, silicon or germanium, which is an elemental semiconductor material. Further, the fin-shaped pattern AF may include a compound semiconductor, and may include, for example, a group IV-IV compound semiconductor or a group III-V compound semiconductor.

The group IV-IV compound semiconductor may include, for example, a binary compound or a ternary compound including at least two or more of carbon (C), silicon (Si), germanium (Ge) and tin (Sn), or a compound obtained by doping these elements with a group IV element. The group III-V compound semiconductor may be, for example, at least one of a binary compound, a ternary compound or a quaternary compound formed by combining at least one of aluminum (Al), gallium (Ga) and indium (In) as a group III element with one of phosphorus (P), arsenic (As) and antimony (Sb) as a group V element.

The field insulating film 15 may be disposed on the substrate 10. The field insulating film 15 may be formed on a part of the side wall of the fin-shaped pattern AF. The fin-shaped pattern AF may protrude above the upper surface of the field insulating film 15. The field insulating film 15 may include, for example, an oxide film, a nitride film, an oxynitride film, or a combined film thereof.

The first gate electrode GE may be disposed on the fin-shaped pattern AF. The first gate electrode GE may extend in the other direction that intersects one direction in which the fin-shaped pattern AF extends. The first gate electrode GE may intersect the fin-shaped pattern AF.

The first gate electrode GE may include, for example, at least one of a metal, a conductive metal nitride, a conductive metal carbonitride, a conductive metal carbide, a metal silicide, a doped semiconductor material, a conductive metal oxynitride, and a conductive metal oxide.

The first gate insulating film GI may be disposed between the first gate electrode GE and the fin-shaped pattern AF, and between the first gate electrode GE and the field insulating film 15. The first gate insulating film GI may include, for example, silicon oxide, silicon oxynitride, silicon nitride, or a high dielectric constant material having a larger dielectric constant than silicon oxide. The high dielectric constant material may include, for example, at least one of boron nitride, metal oxide, and metal silicon oxide.

The semiconductor device according to some embodiments may include a NC (Negative Capacitance) FET using a negative capacitor. For example, the first gate insulating film GI may include a ferroelectric material film having ferroelectric properties, and a paraelectric material film having paraelectric properties.

The ferroelectric material film may have a negative capacitance, and the paraelectric material film may have a positive capacitance. For example, if two or more capacitors are connected in series and the capacitance of each capacitor has a positive value, the overall capacitances decrease from the capacitance of each of the individual capacitors. On the other hand, if at least one of the capacitances of two or more capacitors connected in series has a negative value, the overall capacitances may be greater than an absolute value of each of the individual capacitances, while having a positive value.

When the ferroelectric material film having the negative capacitance and the paraelectric material film having the positive capacitance are connected in series, the overall capacitance values of the ferroelectric material film and the paraelectric material film connected in series may increase. By the use of the increased overall capacitance value, a transistor including the ferroelectric material film may have a subthreshold swing (SS) under 60 mV/decade at room temperature.

The ferroelectric material film may have ferroelectric properties. The ferroelectric material film may include, for example, at least one of hafnium oxide, hafnium zirconium oxide, barium strontium titanium oxide, barium titanium oxide, and lead zirconium titanium oxide. Here, as an example, the hafnium zirconium oxide may be a material obtained by doping hafnium oxide with zirconium (Zr). As another example, the hafnium zirconium oxide may be a compound of hafnium (Hf), zirconium (Zr), and oxygen (O).

The ferroelectric material film may further include a doped dopant. For example, the dopant may include at least one of aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr), and tin (Sn). The type of dopant included in the ferroelectric material film may vary depending on which type of ferroelectric material is included in the ferroelectric material film.

When the ferroelectric material film includes hafnium oxide, the dopant included in the ferroelectric material film may include, for example, at least one of gadolinium (Gd), silicon (Si), zirconium (Zr), aluminum (Al), and yttrium (Y).

When the dopant is aluminum (Al), the ferroelectric material film may include 3 to 8 at % (atomic %) aluminum. Here, a ratio of the dopant may be a ratio of aluminum to the sum of hafnium and aluminum.

When the dopant is silicon (Si), the ferroelectric material film may include 2 to 10 at % silicon. When the dopant is yttrium (Y), the ferroelectric material film may include 2 to 10 at % yttrium. When the dopant is gadolinium (Gd), the ferroelectric material film may include 1 to 7 at % gadolinium. When the dopant is zirconium (Zr), the ferroelectric material film may include 50 to 80 at % zirconium.

The paraelectric material film may have the paraelectric properties. The paraelectric material film may include at least one of, for example, a silicon oxide and a metal oxide having a high dielectric constant. The metal oxide included in the paraelectric material film may include, for example, at least one of hafnium oxide, zirconium oxide, and aluminum oxide.

The ferroelectric material film and the paraelectric material film may include the same material. The ferroelectric material film has the ferroelectric properties, but the paraelectric material film may not have the ferroelectric properties. For example, when the ferroelectric material film and the paraelectric material film include hafnium oxide, a crystal structure of hafnium oxide included in the ferroelectric material film differs from a crystal structure of hafnium oxide included in the paraelectric material film.

The ferroelectric material film may have a thickness having the ferroelectric properties. The thickness of the ferroelectric material film may be, for example, 0.5 to 10 nm. Since a thickness that exhibits the ferroelectric properties may vary for each ferroelectric material, the thickness of the ferroelectric material film may vary depending on the ferroelectric material.

As an example, the first gate insulating film GI may include one ferroelectric material film. As another example, the first gate insulating film GI may each include a plurality of ferroelectric material films spaced apart from each other. The first gate insulating film GI may have a stacked film structure in which the plurality of ferroelectric material films and the plurality of paraelectric material films are alternately stacked.

A gate capping pattern GE_CAP may be disposed on the first gate electrode GE. In one variation, the gate capping pattern GE_CAP may not be disposed on the first gate electrode GE.

The first via pattern 215 and the first wiring pattern 210 may be disposed on the first gate electrode GE. Although the first via pattern 215 is shown as not being connected to the first gate electrode GE, the present disclosure is not limited thereto. In one variation, the first via pattern 215 may be connected to the first gate electrode GE.

Unlike the shown example, a first conductive lower pattern (110 of FIGS. 2 and 3) and a second conductive lower pattern 120 may be further disposed between the first via pattern 215 and the first gate electrode GE.

Since the description of the first via pattern 215 and the first wiring pattern 210 may be substantially the same as that described using FIGS. 1 to 25, the description will not be provided below.

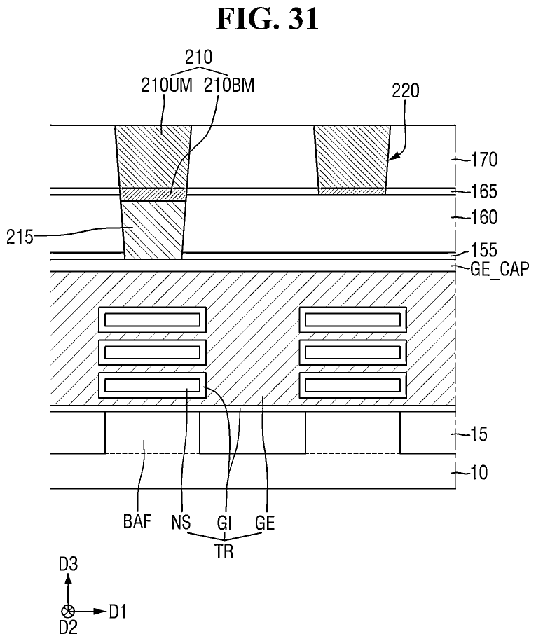

FIG. 31 is a diagram of a semiconductor device according to some embodiments. For convenience of explanation, points that are different from those explained using FIG. 30 will be mainly explained.

Referring to FIG. 31, in the semiconductor device according to some embodiments, the transistor TR may include a nanosheet NS, a first gate electrode GE that at least partially surrounds the nanosheet NS, and a first gate insulating film GI between the nanosheet NS and the first gate electrode GE.

The nanosheet NS may be disposed on the lower fin-shaped pattern BAF. The nanosheet NS may be spaced apart from the lower fin-shaped pattern BAF in the third direction (D3 of FIG. 2). Although the transistor TR is shown to include three nanosheets NS spaced apart in the third direction D3, the embodiments are not limited thereto. It goes without saying that the number of nanosheets NS disposed on the lower fin-shaped pattern BAF in the third direction D3 may be more than three or smaller than three.

The lower fin-shaped pattern BAF and the nanosheet NS may each include, for example, silicon or germanium, which is an elemental semiconductor material. The lower fin-shaped pattern BAF and the nanosheet NS may each include a compound semiconductor, and may include, for example, a group IV-IV compound semiconductor or a group III-V compound semiconductor. The lower fin-shaped pattern BAF and the nanosheet NS may include the same material or may include different materials.

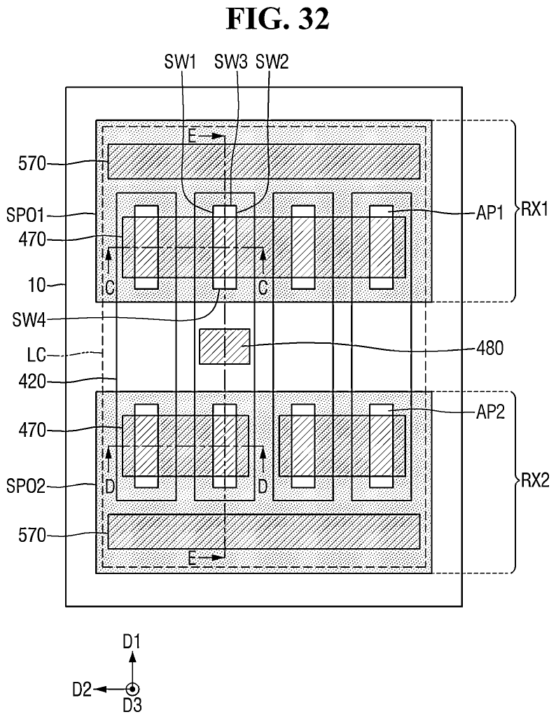

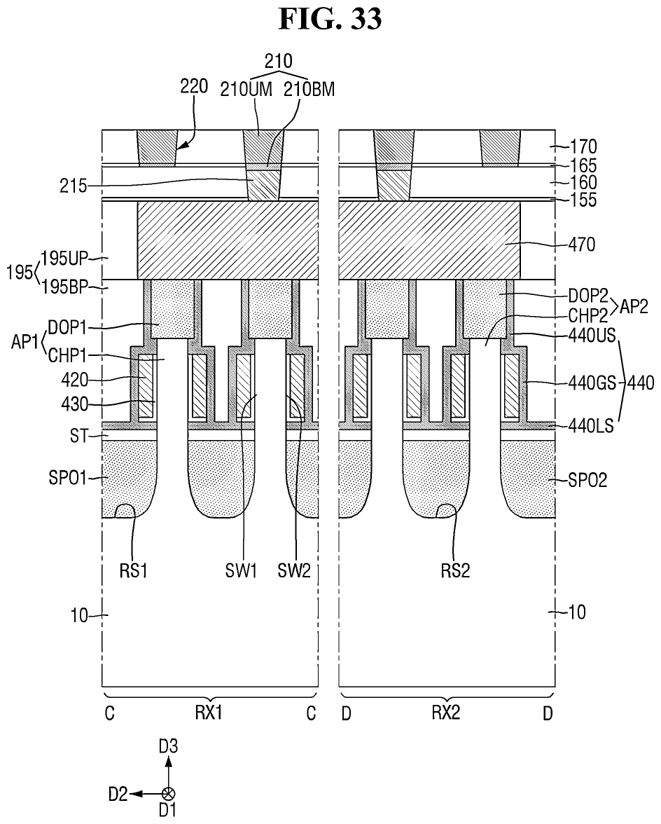

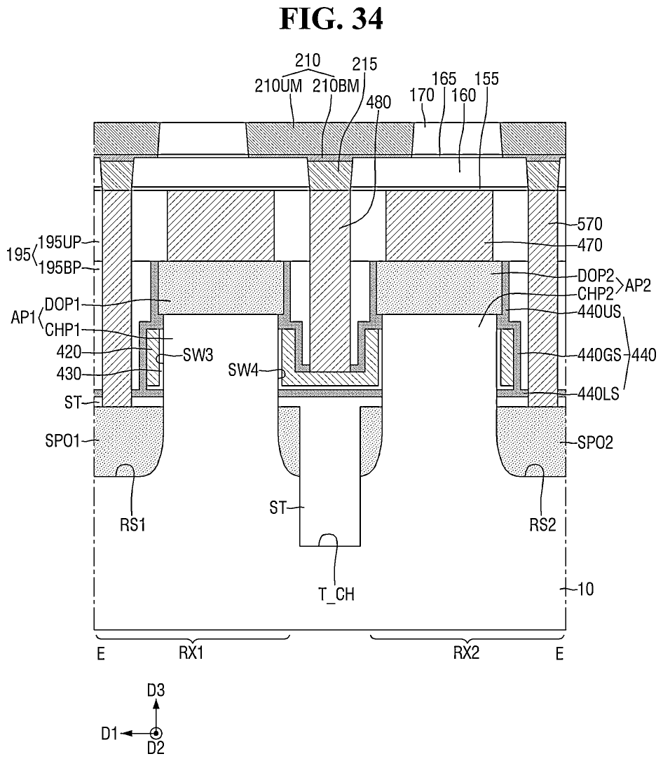

FIGS. 32 to 34 are diagrams of a semiconductor device according to some embodiments. For reference, FIG. 32 is a plan view of a semiconductor device according to some embodiments. FIG. 33 is a cross-sectional view taken along lines C-C and D-D of FIG. 32. FIG. 34 is a cross-sectional view taken along E-E of FIG. 32.

Referring to FIGS. 32 to 34, a logic cell LC may be provided on the substrate 10. The logic cell LC may refer to a logic element (e.g., an inverter, a flip-flop, etc.) that performs a specific function. The logic cell LC may include vertical transistors (Vertical FET) that constitute the logic element, and wirings that connect the vertical transistors together.

The logic cell LC on the substrate 10 may include a first active region RX1 and a second active region RX2. For example, the first active region RX1 may be a PMOSFET region, and the second active region RX2 may be an NMOSFET region. The first and second active regions RX1 and RX2 may be defined by trenches T_CH formed in the upper part of the substrate 10. The first and second active regions RX1 and RX2 may be spaced apart from each other in the first direction D1.

A first lower epitaxial pattern SPO1 may be provided on the first active region RX1, and a second lower epitaxial pattern SPO2 may be provided on the second active region RX2. From a planar viewpoint, the first lower epitaxial pattern SPO1 may overlap the first active region RX1, and the second lower epitaxial pattern SPO2 may overlap the second active region RX2. The first and second lower epitaxial patterns SPO1 and SPO2 may be epitaxial patterns formed by a selective epitaxial growth process. The first lower epitaxial pattern SPO1 may be provided in the first recess region RS1 of the substrate 10, and the second lower epitaxial pattern SPO2 may be provided in the second recess region RS2 of the substrate 10.

The first active patterns AP1 may be provided on the first active region RX1, and the second active patterns AP2 may be provided on the second active region RX2. Each of the first and second active patterns AP1 and AP2 may have a vertically protruding fin shape. From a planar viewpoint, each of the first and second active patterns AP1 and AP2 may have a bar shape extending in the first direction D2. The first active patterns AP1 may be arranged along the second direction D2, and the second active patterns AP2 may be arranged along the second direction D2.

Each first active pattern AP1 may include a first channel pattern CHP1 vertically protruding or extending from the first lower epitaxial pattern SPO1, and a first upper epitaxial pattern DOP1 on the first channel pattern CHP1. Each second active pattern AP2 may include a second channel pattern CHP2 vertically protruding or extending from the second lower epitaxial pattern SPO2, and a second upper epitaxial pattern DOP2 on the second channel pattern CHP2.

An element isolation film ST may be provided on the substrate 10 to fill or be in the trench T_CH. The element isolation film ST may cover or overlap upper surfaces of the first and second lower epitaxial patterns SPO1 and SPO2. The first and second active patterns AP1 and AP2 may protrude perpendicularly onto the isolation layer ST.

A plurality of second gate electrodes 420 extending parallel to each other in the first direction D1 may be provided on the element isolation film ST. The second gate electrodes 420 may be arranged along the second direction D2. The second gate electrode 420 may at least partially surround the first channel pattern CHP1 of the first active pattern AP1, and may at least partially surround the second channel pattern CHP2 of the second active pattern AP2. For example, the first channel pattern CHP1 of the first active pattern AP1 may have first to fourth side walls SW1 to SW4. The first and second side walls SW1 and SW2 may be opposite to each other in the second direction D2, and the third and fourth side walls SW3 and SW4 may be opposite to each other in the first direction D1. The second gate electrode 420 may be provided on the first to fourth side walls SW1 to SW4. In other words, the second gate electrode 420 may surround the first to fourth side walls SW1 to SW4.

A second gate insulating film 430 may be interposed between the second gate electrode 420 and each of the first and second channel patterns CHP1 and CHP2. The second gate insulating film 430 may cover or overlap a bottom surface of the second gate electrode 420 and an inner wall of the second gate electrode 420. For example, the second gate insulating film 430 may directly cover or overlap the first to fourth side walls SW1 to SW4 of the first active pattern AP1.

The first and second upper epitaxial patterns DOP1 and DOP2 may protrude or extend vertically above the second gate electrode 420. The upper surface of the second gate electrode 420 may be lower than the bottom surfaces of each of the first and second upper epitaxial patterns DOP1 and DOP2 in the third direction. In other words, each of the first and second active patterns AP1 and AP2 may have a structure that vertically protrudes or extends from the substrate 10 and penetrates the second gate electrode 420.

The semiconductor element according to the present embodiment may include vertical transistors in which carriers move in the third direction D3. For example, when a voltage is applied to the second gate electrode 420 and the transistor is turned “on”, the carriers may move from the lower epitaxial patterns SOP1 and SOP2 to the upper epitaxial patterns DOP1 and DOP2 through the channel patterns CHP1 and CHP2. In the semiconductor device according to some embodiments, the second gate electrode 420 may completely surround side walls SW1 to SW4 of the channel patterns CHP1 and CHP2. The transistor according to the present disclosure may be a three-dimensional field effect transistor (e.g., VFET) having a gate all-around structure. Since the gate surrounds the channel, the semiconductor element according to the disclosure may have excellent electrical properties.

A spacer 440 that covers or overlaps the second gate electrodes 420 and the first and second active patterns AP1 and AP2 may be provided on the element isolation film ST. The spacer 440 may include a silicon nitride film or a silicon oxynitride film. The spacer 440 may include a lower spacer 440LS, an upper spacer 440US, and a gate spacer 440GS between the lower and upper spacers 440LS and 440US.

The lower spacer 440LS may directly cover or overlap the upper surface of the element isolation film ST. The second gate electrodes 420 may be spaced apart from the element isolation film ST in the third direction D3 by the lower spacer 440LS. The gate spacer 440GS may cover or overlap the upper surfaces and the outer side walls of each of the second gate electrodes 420. The upper spacer 440US may cover or overlap the first and second upper epitaxial patterns DOP1 and DOP2. However, the upper spacer 440US does not cover or overlap the upper surfaces of the first and second upper epitaxial patterns DOP1 and DOP2, and may expose the upper surfaces of the first and second upper epitaxial patterns DOP1 and DOP2.

A first portion 195BP of the lower interlayer insulating film may be provided on the spacer 440. An upper surface of the first portion 195BP of the lower interlayer insulating film may be substantially coplanar with the upper surfaces of the first and second upper epitaxial patterns DOP1 and DOP2. A second portion 195UP of the lower interlayer insulating film and first and second interlayer insulating films 160 and 170 may be sequentially stacked on the first portion 195BP of the lower interlayer insulating film. The first portion 195BP of the lower interlayer insulating film and the second portion 195UP of the lower interlayer insulating film may be included in the lower interlayer insulating film 195. The second portion 195UP of the lower interlayer insulating film may cover or overlap the upper surfaces of the first and second upper epitaxial patterns DOP1 and DOP2.

At least one first source/drain contact 470 that extends into or penetrates the second portion 195UP of the lower interlayer insulating film and is connected to the first and second upper epitaxial patterns DOP1 and DOP2 may be provided. At least one second source/drain contact 570 that sequentially extends into or sequentially penetrates the lower interlayer insulating film 195, the lower spacer 440LS and the element isolation film ST and is connected to the first and second lower epitaxial patterns SPO1 and SPO2 may be provided. A gate contact 480 that sequentially extends into or penetrates the second portion 195UP of the lower interlayer insulating film, the first portion 195BP of the lower interlayer insulating film, and the gate spacer 440GS and is connected to the second gate electrode 420 may be provided.

The first etching stop film 155 may be further disposed between the second portion 195UP of the lower interlayer insulating film and the second interlayer insulating film 160. The second etching stop film 165 may be disposed between the second interlayer insulating film 160 and the third interlayer insulating film 170.

The first via pattern 215 and the first wiring pattern 210 may be provided on the first source/drain contact 470, the second source/drain contact 570, and the gate contact 480. The first via pattern 215 may be connected to the first source/drain contact 470, the second source/drain contact 570, and the gate contact 480.

In one variation, additional wiring similar to the first conductive lower pattern 110 may be further disposed, for example, between the first source/drain contact 470 and the first via pattern 215.

The detailed description of the first via pattern 215 and the first wiring pattern 210 may be substantially the same as that described above using FIGS. 1 to 25.

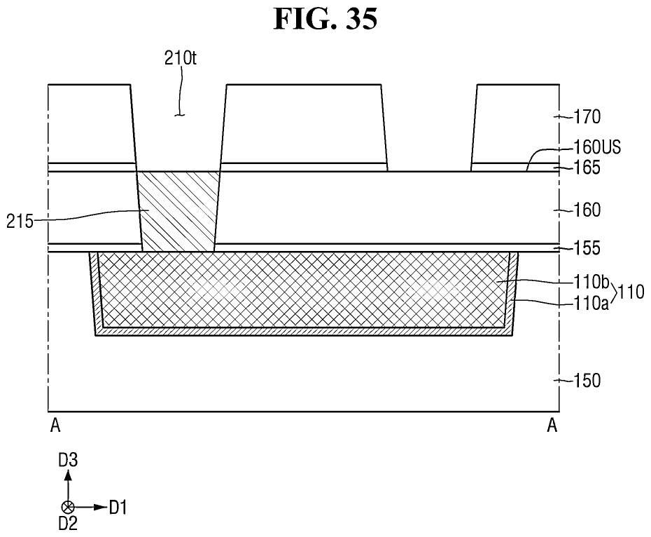

FIGS. 35 to 37 are intermediate stage diagrams of a method for fabricating a semiconductor device according to some embodiments. For reference, FIGS. 35 to 37 may be cross-sectional views taken along A-A of FIG. 1.

Referring to FIG. 35, the first conductive lower pattern 110 may be formed in the first interlayer insulating film 150.

The first etching stop film 155 may be sequentially formed on the first interlayer insulating film 150 and the first conductive lower pattern 110. The second interlayer insulating film 160 may be formed on the first etching stop film 155.

A via pattern hole may be formed in the first etching stop film 155 and the second interlayer insulating film 160. The via pattern hole may expose a part of the first conductive lower pattern 110. A first via pattern 215 may be formed in the via pattern hole. The first via pattern 215 may be formed in the second interlayer insulating film 160.

Subsequently, the second etching stop film 165 may be formed along the upper surface 160US of the second interlayer insulating film. The third interlayer insulating film 170 may be formed on the second etching stop film 165.

A wiring pattern trench 210t may be formed in the third interlayer insulating film 170 and the second etching stop film 165. The wiring pattern trench 210t may penetrate or extend into the second etching stop film 165 and expose the first via pattern 215. The wiring pattern trench 210t may extend in the second direction D2.

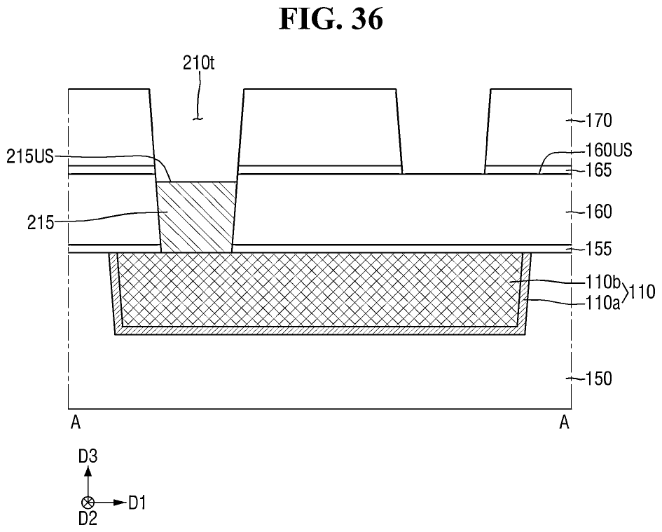

Referring to FIG. 36, a part of the first via pattern 215 exposed by the wiring pattern trench 210t may be removed.

Accordingly, the upper surface 215US of the first via pattern may be lowered. Based on the upper surface of the first conductive lower pattern 110, the upper surface 215US of the first via pattern may be lower than the upper surface 160US of the second interlayer insulating film.

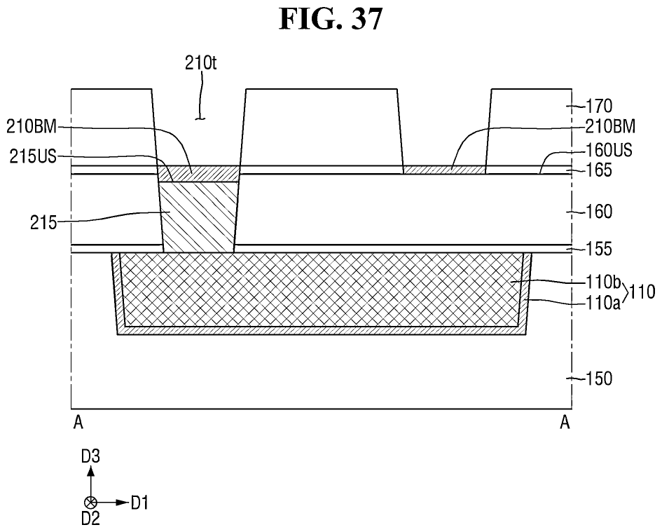

Referring to FIG. 37, a first lower metal wiring line 210BM may be formed in the wiring pattern trench 210t.

The first lower metal wiring line 210BM may partially fill or be in the wiring pattern trench 210t. The first lower metal wiring line 210BM may be in contact with the upper surface 215US of the first via pattern.

A thickness of the first lower metal wiring line 210BM formed on the upper surface 215US of the first via pattern may be different from a thickness of the first lower metal wiring line 210BM formed on the upper surface 160US of the second interlayer insulating film. For example, the first lower metal wiring line 210BM may be formed, using a deposition method in which the deposition thickness may vary depending on the type of material exposed in the portion in which the first lower metal wiring line 210BM is deposited. That is, the thickness of the first lower metal wiring line 210BM formed on the conductive material may be different from the thickness of the first lower metal wiring line 210BM formed on the insulating material. Further, the thickness of the deposited first lower metal wiring line 210BM may vary depending on the type of insulating material.

Next, referring to FIG. 2, the first upper metal wiring line 210UM may be formed on the first lower metal wiring line 210BM. The first upper metal wiring line 210UM may fill the remainder of the wiring pattern trench 210t. The first upper metal wiring line 210UM may be formed using, for example, a bottom-up growth method. Accordingly, the first wiring pattern 210 including the first upper metal wiring line 210UM and the first lower metal wiring line 210BM may be formed.

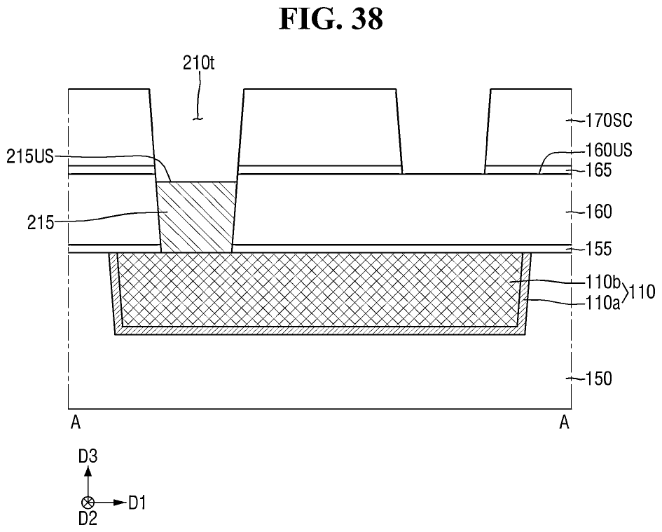

FIGS. 38 to 42 are intermediate stage diagrams of a method for fabricating a semiconductor device according to some embodiments.

Referring to FIG. 38, the first conductive lower pattern 110 may be formed in the first interlayer insulating film 150.

The first etching stop film 155 and the second interlayer insulating film 160 may be sequentially formed on the first interlayer insulating film 160. The first via pattern 215 may be formed in the first etching stop film 155 and the second interlayer insulating film 160.

Subsequently, the second etching stop film 165 and the sacrificial interlayer insulating film 170SC may be sequentially formed on the second interlayer insulating film 160. The wiring pattern trench 210t may be formed in the sacrificial interlayer insulating film 170SC and the second etching stop film 165.

The sacrificial interlayer insulating film 170SC may include a material different from that of the second interlayer insulating film 160. For example, the second interlayer insulating film 160 may include silicon oxide, and the sacrificial interlayer insulating film 170SC may include silicon nitride, but the embodiments are not limited thereto.

Subsequently, a part of the first via pattern 215 may be removed to reduce the height of the first via pattern 215. The upper surface 215US of the first via pattern may be lower than the upper surface 160US of the second interlayer insulating film in the third direction.

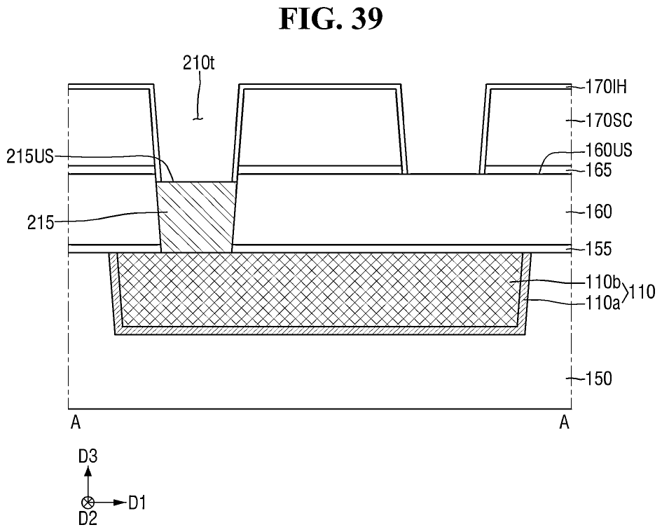

Referring to FIG. 39, a selective inhibition film 170IH may be formed along the side walls of the wiring pattern trench 210t and the upper surface of the sacrificial interlayer insulating film 170SC.

The selective inhibition film 170IH may not be formed on the upper surface 215US of the first via pattern and the upper surface 160US of the second interlayer insulating film. For example, the selective inhibition film 170IH may be selectively formed on the sacrificial interlayer insulating film 170SC.

The selective inhibition film 170IH includes an organic material. The selective inhibition film 170IH may prevent a conductive material from being deposited on the surface on which the selective inhibition film 170IH is formed.

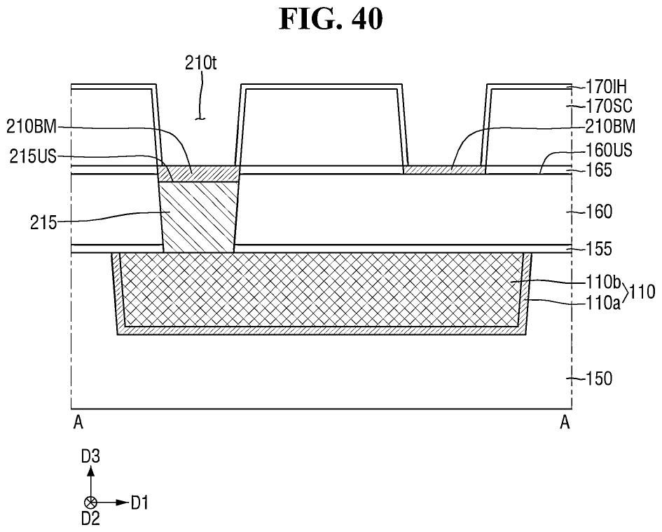

Referring to FIG. 40, the first lower metal wiring line 210BM may be formed in the wiring pattern trench 210t in the state in which the selective inhibition film 170IH is formed.

The first lower metal wiring line 210BM may partially fill or be in the wiring pattern trench 210t. The thickness of the first lower metal wiring line 210BM formed on the upper surface 215US of the first via pattern may be different from the thickness of the first lower metal wiring line 210BM formed on the upper surface 160US of the second interlayer insulating film.

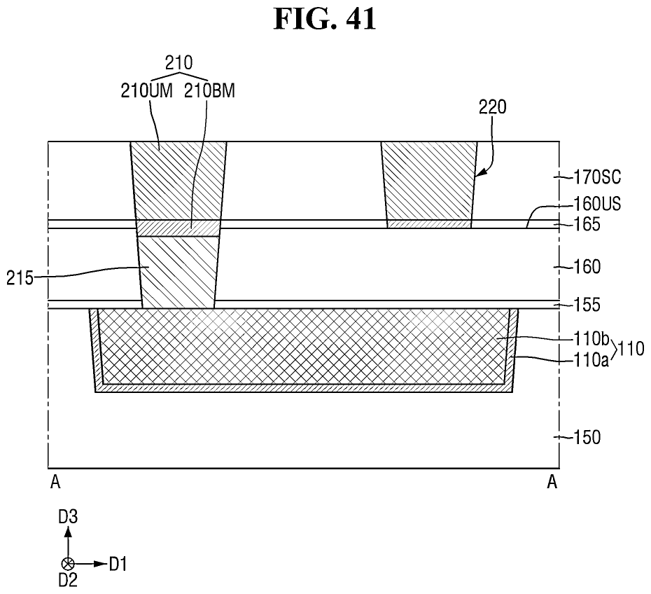

Referring to FIGS. 40 and 41, the selective inhibition film 170IH may be removed.

Subsequently, the first upper metal wiring line 210UM may be formed on the first lower metal wiring line 210BM. The first wiring pattern 210 may be formed on the first via pattern 215.

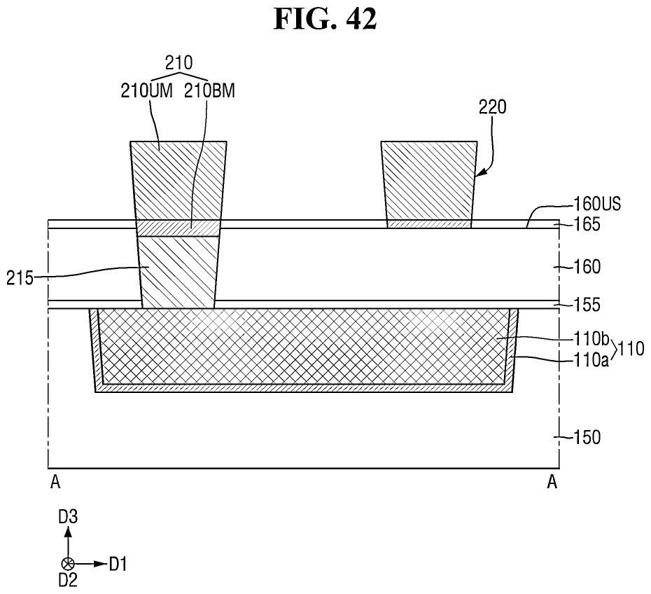

Referring to FIGS. 41 and 42, the sacrificial interlayer insulating film 170SC may be removed.

The first wiring pattern 210 may protrude beyond the second etching stop film 165 in the third direction D3. A side wall of the first upper metal wiring line 210UM may be exposed.

Next, referring to FIG. 8, the third interlayer insulating film 170 may be formed on the second etching stop film 165. The third interlayer insulating film 170 may cover or overlap the side walls of the first wiring pattern 210. The third interlayer insulating film 170 may include a wiring insulating liner 170LI and a filling interlayer insulating film 170FI. In one variation, the third interlayer insulating film 170 may be a single film, as shown in FIG. 2.

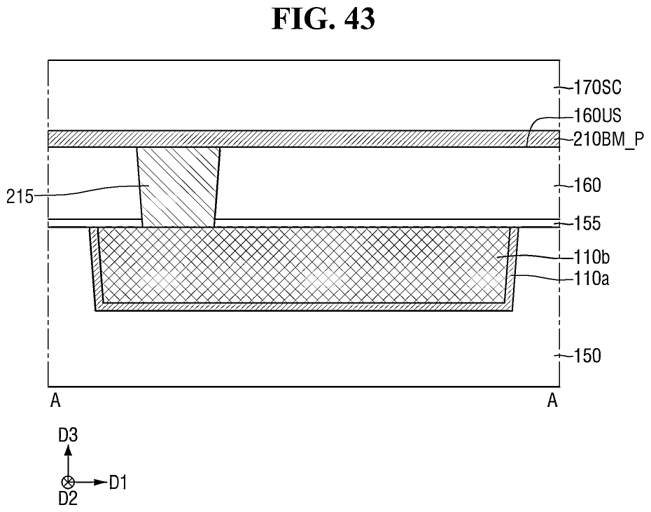

FIGS. 43 to 47 are intermediate stage diagrams of a method for fabricating a semiconductor device according to some embodiments.

Referring to FIG. 43, a first conductive lower pattern 110 may be formed in the first interlayer insulating film 150. The first etching stop film 155 and the second interlayer insulating film 160 may be sequentially formed on the first interlayer insulating film 160. The first via pattern 215 may be formed in the first etching stop film 155 and the second interlayer insulating film 160.

Subsequently, a lower metal wiring film 210BM_P may be formed on the second interlayer insulating film 160 and the first via pattern 215. The lower metal wiring film 210BM_P may be formed along the upper surface 160US of the second interlayer insulating film. The lower metal wiring film 210BM_P is connected to the first via pattern 215.

The sacrificial interlayer insulating film 170SC may be formed on the lower metal wiring film 210BM_P. For example, the sacrificial interlayer insulating film 170SC may include an insulating material.

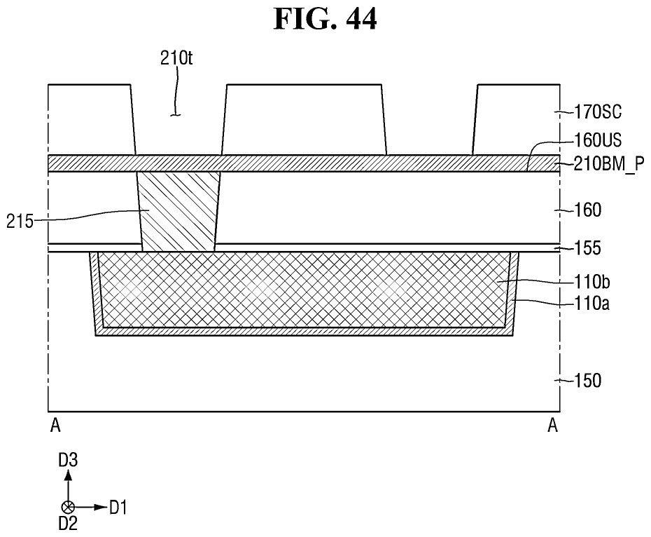

Referring to FIG. 44, the wiring pattern trench 210t may be formed in the sacrificial interlayer insulating film 170SC.

The wiring pattern trench 210t may expose the lower metal wiring film 210BM_P.

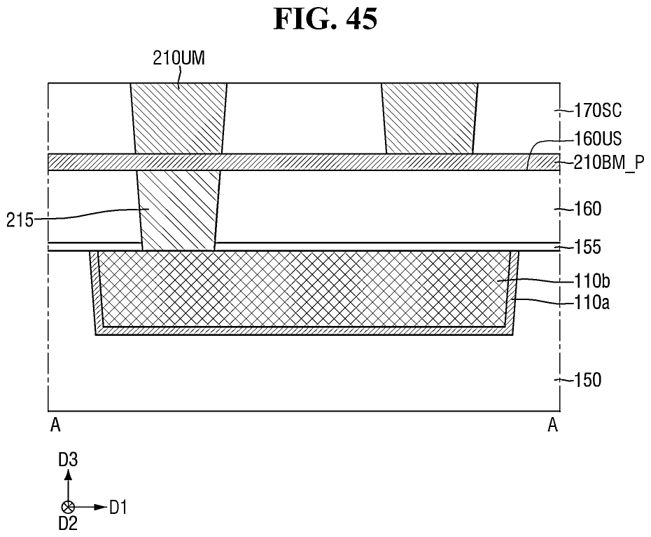

Referring to FIGS. 44 and 45, the first upper metal wiring line 210UM may be formed on the lower metal wiring film 210BM_P.

The first upper metal wiring line 210UM may fill the wiring pattern trench 210t. The first upper metal wiring line 210UM may be formed using, for example, a bottom-up growth method.

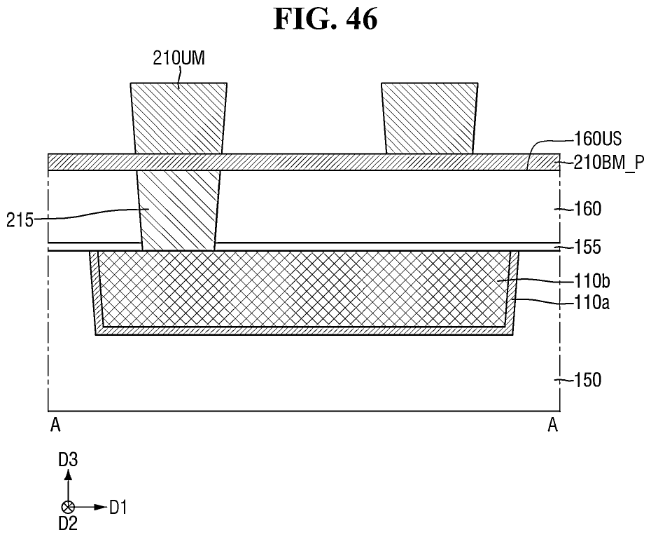

Referring to FIGS. 45 and 46, the sacrificial interlayer insulating film 170SC may be removed to expose the side walls of the first upper metal wiring line 210UM.

The lower metal wiring film 210BM_P covered or overlapped with the sacrificial interlayer insulating film 170SC may be exposed.

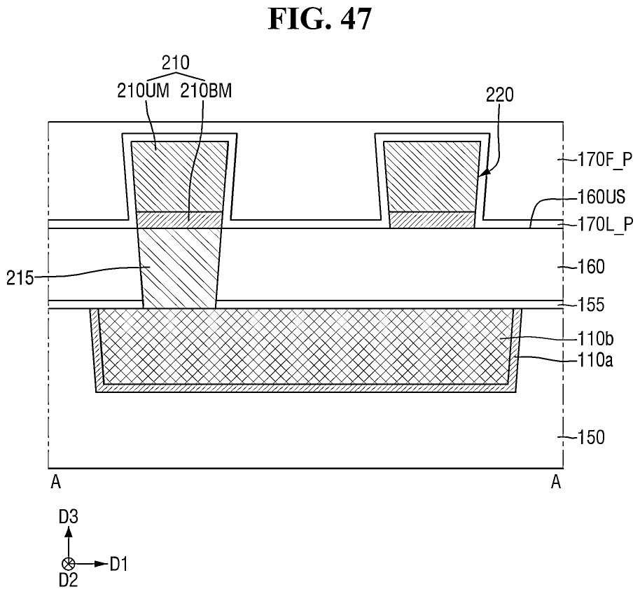

Referring to FIGS. 46 and 47, the lower metal wiring film 210BM_P that does not overlap the first upper metal wiring line 210UM in the third direction D3 may be removed, by using the first upper metal wiring line 210UM as a mask.

The first lower metal wiring line 210BM may be formed between the first upper metal wiring line 210UM and the first via pattern 215 through patterning of the lower metal wiring film 210BM_P. The first wiring pattern 210 may be formed on the first via pattern 215. While the first wiring pattern 210 is being formed, the second wiring pattern 220 including the first upper metal wiring line 210UM and the first lower metal wiring line 210BM may be formed on the second interlayer insulating film 160.

Next, a pre-wiring insulating liner 170L_P may be formed along the upper surface 160 of the second interlayer insulating film, the side walls and upper surface of the first wiring pattern 210, and the side walls and upper surface of the second wiring pattern 220. A pre-filling interlayer insulating film 170F_P may be formed on the pre-wiring insulating liner 170L_P.

Subsequently, a part of the pre-filling interlayer insulating film 170F_P and a part of the pre-wiring insulating liner 170L_P may be removed, using a planarization process. The upper surface of the first wiring pattern 210 and the upper surface of the second wiring pattern 220 may be exposed.

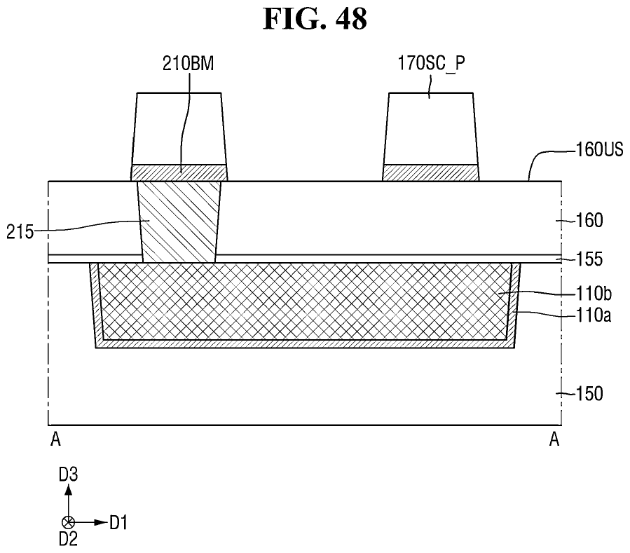

FIGS. 48 to 51 are intermediate stage diagrams of a method for fabricating a semiconductor device according to some embodiments. For reference, FIG. 48 may be a fabricating process performed after FIG. 43.

Referring to FIG. 48, the first lower metal wiring line 210BM and the sacrificial interlayer insulating pattern 170SC_P may be formed by patterning the lower metal wiring film 210BM_P and the sacrificial interlayer insulating film 170SC.

The first lower metal wiring line 210BM and the sacrificial interlayer insulating pattern 170SC_P may be formed on the second interlayer insulating film 160.

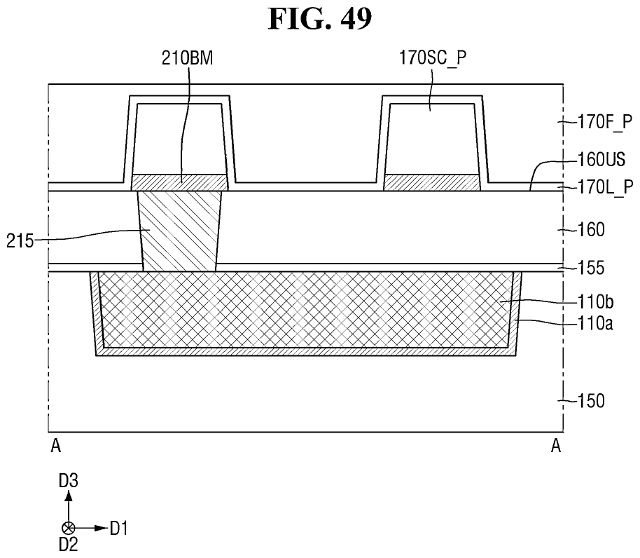

Referring to FIG. 49, the pre-wiring insulating liner 170L_P may be formed on the upper surface 160 of the second interlayer insulating film, the side walls of the first lower metal wiring line 210BM, and the side walls and upper surface of the sacrificial interlayer insulating pattern 170SC_P.

The pre-filling interlayer insulating film 170F_P may be formed on the pre-wiring insulating liner 170L_P.

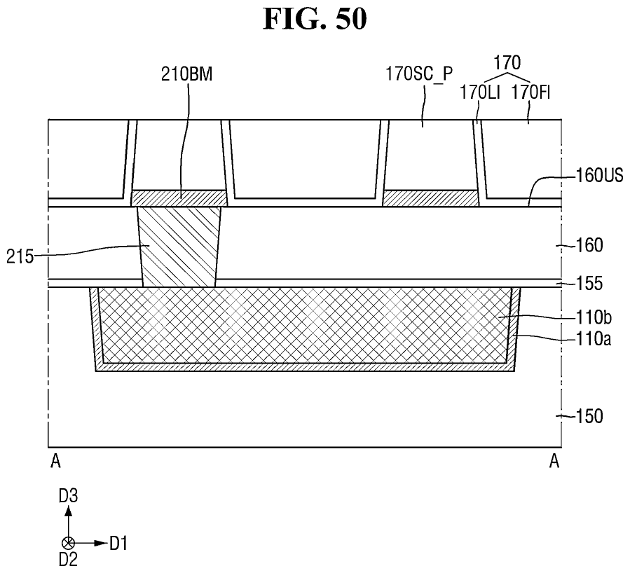

Referring to FIGS. 49 and 50, a part of the pre-filling interlayer insulating film 170F_P and a part of the pre-wiring insulating liner 170L_P may be removed, using a planarization process.

Accordingly, the third interlayer insulating film 170 including the wiring insulating liner 170LI and the filling interlayer insulating film 170FI may be formed. After the planarization process is performed, the upper surface of the sacrificial interlayer insulating pattern 170SC_P may be exposed.

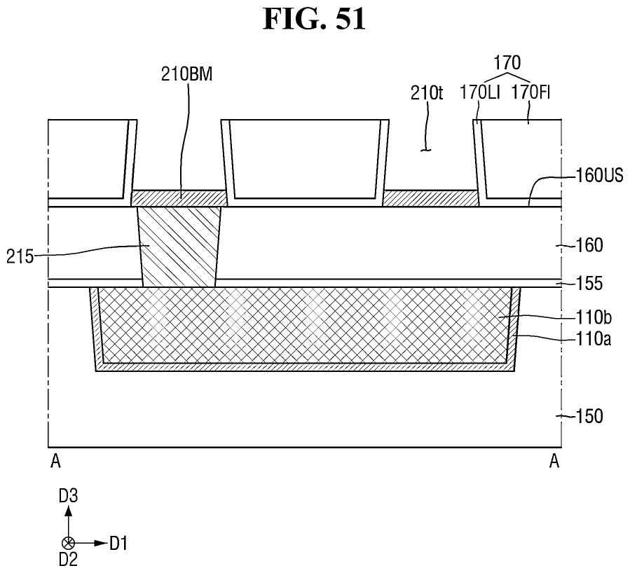

Referring to FIGS. 50 and 51, the sacrificial interlayer insulating pattern 170SC_P may be removed to form the wiring pattern trench 210t inside the third interlayer insulating film 170.

The upper surface of the first lower metal wiring line 210BM is exposed.

Subsequently, the first upper metal wiring line 210UM may be formed in the wiring pattern trench 210t. The first upper metal wiring line 210UM may fill or be in the wiring pattern trench 210t.

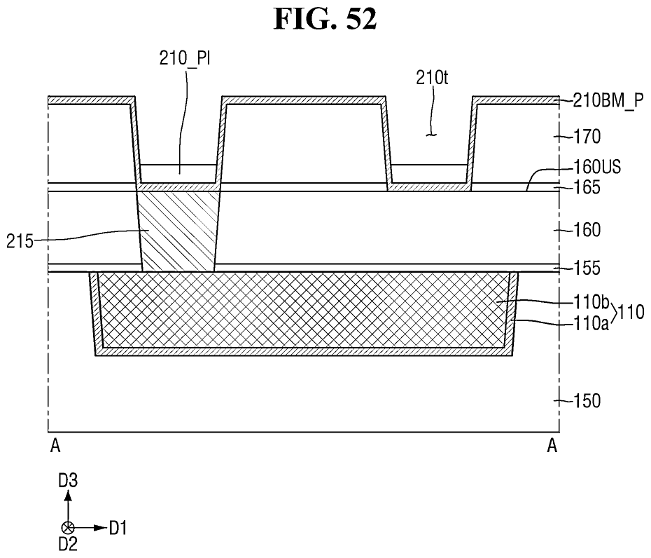

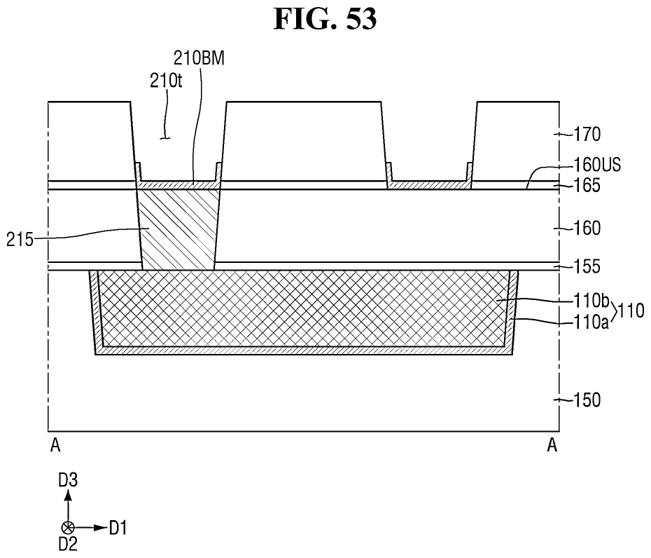

FIGS. 52 and 53 are intermediate stage diagrams of a method for fabricating a semiconductor device according to some embodiments. For reference, FIG. 52 may be a fabricating process performed after FIG. 35.

Referring to FIG. 52, the lower metal wiring film 210BM_P may be formed along the side wall and bottom surface of the wiring pattern trench 210t and the upper surface of the third interlayer insulating film 170.

A blocking pattern 210_P1 may then be formed in the wiring pattern trench 210t. The blocking pattern 210_P1 partially fills or is partially in the wiring pattern trench 210t. A part of the lower metal wiring film 210BM_P that is not covered or overlapped with the blocking pattern 210_P1 is exposed.

Referring to FIGS. 52 and 53, the first lower metal wiring line 210BM may be formed in the wiring pattern trench 210t by removing a part of the lower metal wiring film 210BM_P.

The exposed lower metal wiring film 210BM_P may be removed, by using the blocking pattern 210_P1 as a mask. After forming the first lower metal wiring line 210BM, the blocking pattern 210_P1 may be removed.

Next, referring to FIG. 19, the first upper metal wiring line 210UM may be formed on the first lower metal wiring line 210BM. The first upper metal wiring line 210UM may fill or be in the remainder of the wiring pattern trench 210t.

Although the embodiments of the present disclosure have been described with reference to the accompanying drawings, the present disclosure is not limited to the above embodiments and may be implemented in various different forms. Those of ordinary skill in the technical field to which the present disclosure belongs will be able to understand that the present disclosure may be implemented in other specific forms without changing the technical idea or essential characteristics of the present disclosure. Therefore, it should be understood that the embodiments as described above are not restrictive but illustrative in all respects.

What is claimed is:

1. A semiconductor device comprising:
a via pattern in a first interlayer insulating film; and
a wiring pattern that extends in a first direction and is on the first interlayer insulating film and the via pattern,
wherein the wiring pattern comprises a lower wiring line and an upper wiring line on the lower wiring line,
wherein the lower wiring line and the upper wiring line are stacked in a second direction,
wherein the lower wiring line is between the via pattern and the upper wiring line and is on an upper surface of the via pattern,
wherein a first portion of the lower wiring line is on the upper surface of the via pattern and has a first thickness, and
wherein a second portion of the lower wiring line is on an upper surface of the first interlayer insulating film and has a second thickness that is different from the first thickness.

2. The semiconductor device of claim 1, wherein the first thickness is greater than the second thickness.

3. The semiconductor device of claim 1, wherein:
the upper wiring line comprises a first metal comprising molybdenum (Mo), ruthenium (Ru), or tungsten (W),
the lower wiring line comprises a second metal comprising ruthenium (Ru), cobalt (Co), or tungsten (W), and
the first metal and the second metal are different.

4. The semiconductor device of claim 1, further comprising:
a second interlayer insulating film on the first interlayer insulating film,
wherein the upper wiring line is in and contacts the second interlayer insulating film.

5. The semiconductor device of claim 1, wherein in the second direction, the upper surface of the via pattern is lower than the upper surface of the first interlayer insulating film.

6. The semiconductor device of claim 1, wherein:
the upper wiring line comprises a bottom surface that faces the via pattern and a side wall that extends in the second direction, and
the lower wiring line extends along the bottom surface of the upper wiring line and the side wall of the upper wiring line.

7. The semiconductor device of claim 1, wherein:
the first interlayer insulating film comprises a first lower interlayer insulating film and a first upper interlayer insulating film on the first lower interlayer insulating film,
the lower wiring line contacts the first upper interlayer insulating film,
the first upper interlayer insulating film comprises silicon oxide, and
the first lower interlayer insulating film comprises a material having a dielectric constant that is less than a dielectric constant of silicon oxide.

8. The semiconductor device of claim 1, further comprising a second interlayer insulating film on the first interlayer insulating film, wherein the second interlayer insulating film comprises:
a wiring insulating liner that extends along the upper surface of the first interlayer insulating film and a side wall of the wiring pattern, and
a filling interlayer insulating film on the wiring insulating liner.

9. A semiconductor device comprising:
a via pattern in a first interlayer insulating film;
a wiring pattern that extends in a first direction and is on the first interlayer insulating film and the via pattern, wherein the wiring pattern comprises a lower wiring line and an upper wiring line on the lower wiring line, and wherein the lower wiring line and the upper wiring line are stacked in a second direction; and
a second interlayer insulating film that is on the first interlayer insulating film, wherein the second interlayer insulating film comprises a wiring insulating liner that extends along a side wall of the wiring pattern and an upper surface of the first interlayer insulating film, and wherein the second interlayer insulating film comprises a filling interlayer insulating film on the wiring insulating liner,
wherein the upper wiring line comprises an upper surface and a bottom surface that are opposite to each other in the second direction,
wherein the upper wiring line comprises a side wall that contacts the upper surface of the upper wiring line and the bottom surface of the upper wiring line,
wherein the lower wiring line is between an upper surface of the via pattern and the bottom surface of the upper wiring line,
wherein the lower wiring line contacts the upper surface of the via pattern, and
wherein the lower wiring line does not extend along the side wall of the upper wiring line.

10. The semiconductor device of claim 9, wherein a width of the upper surface of the upper wiring line in a third direction is less than a width of the bottom surface of the upper wiring line in the third direction.

11. The semiconductor device of claim 9, wherein a width of the upper surface of the upper wiring line in a third direction is greater than a width of the bottom surface of the upper wiring line in the third direction.

12. The semiconductor device of claim 9, wherein a width of the lower wiring line in a third direction is less than a width of the bottom surface of the upper wiring line in the third direction.

13. The semiconductor device of claim 9, wherein a width of the lower wiring line in a third direction is the same as a width of the bottom surface of the upper wiring line in the third direction.

14. The semiconductor device of claim 9, wherein:
the upper wiring line comprises a first metal comprising one of molybdenum (Mo), ruthenium (Ru), and tungsten (W),
the lower wiring line comprises a second metal comprising one of ruthenium (Ru), cobalt (Co), and tungsten (W), and
the first metal and the second metal are different.

15. The semiconductor device of claim 9, wherein the filling interlayer insulating film defines an air gap.

16. The semiconductor device of claim 9, wherein the wiring insulating liner contacts the upper surface of the first interlayer insulating film.

17. A semiconductor device comprising:
a via pattern in a first interlayer insulating film; and
a wiring pattern that extends in a first direction and is on the first interlayer insulating film and the via pattern, wherein the wiring pattern comprises a lower wiring line and an upper wiring line on the lower wiring line, and wherein the lower wiring line and the upper wiring line are stacked in a second direction,
wherein the upper wiring line comprises an upper surface and a bottom surface opposite to each other in the second direction,
wherein the upper wiring line comprises a side wall that connects the upper surface of the upper wiring line and the bottom surface of the upper wiring line,
wherein the lower wiring line is between an upper surface of the via pattern and the bottom surface of the upper wiring line,
wherein the lower wiring line contacts the upper surface of the via pattern,
wherein the lower wiring line comprises a first portion that extends along a part of the side wall of the upper wiring line and a second portion that extends along the bottom surface of the upper wiring line, and
wherein the upper wiring line overlaps an uppermost surface of the lower wiring line in the first direction.

18. The semiconductor device of claim 17, wherein a thickness of the second portion is greater than a thickness of the first portion.

19. The semiconductor device of claim 17, further comprising a second interlayer insulating film on the first interlayer insulating film, wherein the second interlayer insulating film comprises:
a wiring insulating liner that extends along the upper surface of the first interlayer insulating film and the side wall of the upper wiring line, and
a filling interlayer insulating film on the wiring insulating liner.

20. The semiconductor device of claim 17, wherein:
the upper wiring line comprises a first metal comprising molybdenum (Mo), ruthenium (Ru), or tungsten (W),
the lower wiring line comprises a second metal comprising ruthenium (Ru), cobalt (Co), or tungsten (W), and
the first metal and the second metal are different.
